(19) United States
(12) Patent Application Publication
(10) Pub. No.: US 2026/0262416 A1
(43) Pub. Date: Sep. 3, 2026

(54) DISPLAY PANEL AND DISPLAY DEVICE

(71) Applicant: BOE TECHNOLOGY GROUP CO., LTD., Beijing (CN)

(72) Inventors: Cheng HAN, Beijing (CN); Yansong LI, Beijing (CN); Yanming WANG, Beijing (CN); Oixiao WU, Beijing (CN); Xu LI, Beijing (CN); Hao GAO, Beijing (CN); Shun WANG, Beijing (CN); Le WANG, Beijing (CN); Songquan WU, Beijing (CN)

(21) Appl. No.: 18/995,750

(22) PCT Filed: Nov. 18, 2022
(86) PCT No.: PCT/CN2022/132995

§ 371 Date: Jan. 16, 2025

(51) Int. Cl. H10K 59/80; H10K 59/40

(52) U.S. Cl. CPC H10K 59/873; H10K 59/40; H10K 59/879

(57) ABSTRACT

A display panel includes a display substrate and a light modulation layer group wherein the light modulation layer group is arranged on a light-emergent side of the display substrate; the display substrate includes a plurality of sub-pixels and the light modulation layer group includes a second film layer which is arranged on the light-emergent side of the display substrate and includes a plurality of first protrusion portions and a plurality of first extension portions, the orthographic projections of the first protrusion portions on the display substrate overlapping with the sub-pixels, and the orthographic projections of the first extension portions on the display substrate not overlapping with the sub-pixels.

### TECHNICAL FIELD

The present disclosure relates to the field of display technology, and in particular, to a display panel and a display device.

### BACKGROUND

OLED (Organic Light Emitting Display) panels have many advantages such as self-luminescence, high brightness, wide viewing angle, short response time, high clarity and contrast, and the ability of being produced by R, G, B full-color components, etc., and are gradually becoming the first choice for display devices. However, with the continuous development of science and technology, people's purposeful demand for OLED devices is also gradually increasing.

It should be noted that the information disclosed in the above background technology section is only used to enhance understanding the background of the present disclosure, and therefore may include information that does not constitute the prior art known to those skilled in the art.

### SUMMARY

The present disclosure is directed to overcome deficiencies of the above-mentioned related art and provide a display panel and a display device.

According to an aspect of the present disclosure, there is provided a display panel, including:
a display substrate and a light modulation layer group, where the light modulation layer group is provided on a light-emitting side of the display substrate, the display substrate includes a plurality of sub-pixels, and the light modulation layer group includes:
a second film layer, provided on the light-emitting side of the display substrate, where the second film layer includes a plurality of first protrusions and a plurality of first extensions, orthographic projections of the first protrusions on the display substrate overlap with the sub-pixels, and orthographic projections of the first extensions on the display substrate do not overlap with the sub-pixels.

In some exemplary embodiments of the present disclosure, the display panel further includes:
a first film layer, provided between the display substrate and the second film layer, where a difference between a refractive index of the second film layer and a refractive index of the first film layer is less than or equal to 15% of the refractive index of the first film layer.

In some exemplary embodiments of the present disclosure, a width of the first extension in a first direction is less than or equal to a length of a shortest side, close to the first extension, of an adjacent one of the sub-pixels, and the first direction is parallel to the shortest side.

In some exemplary embodiments of the present disclosure, the width of the first extension in the first direction is greater than or equal to 0.5 microns and less than or equal to 30 microns.

In some exemplary embodiments of the present disclosure, an extending direction of the first extension intersects with a first edge of an adjacent one of the sub-pixels with an intersection angle being greater than or equal to 45 degrees, the first edge is a side edge of the sub-pixel close to the first extension, and the extending direction is a direction in which the first protrusion points to the first extension.

In some exemplary embodiments of the present disclosure, the first extension is connected to the first protrusion.

In some exemplary embodiments of the present disclosure, a first side line of the first protrusion is connected to one of the first extensions, a width of the first extension in a second direction is less than or equal to a length of the first side line, and the second direction is parallel to the first side line.

In some exemplary embodiments of the present disclosure, a first side line of the first protrusion is connected to at least two of the first extensions, sum of widths of the at least two of the first extensions in a second direction is less than or equal to a length of the first side line, and the second direction is parallel to the first side line.

In some exemplary embodiments of the present disclosure, the first extension is connected to a first side line of the first protrusion, the extending direction of the first extension intersects with the first side line with an intersection angle being greater than or equal to 45 degrees, and the extending direction is the direction in which the first protrusion points to the first extension.

In some exemplary embodiments of the present disclosure, the first extension is connected between adjacent two of the first protrusions.

In some exemplary embodiments of the present disclosure, two adjacent sub-pixels are a first sub-pixel and a second sub-pixel, and the first extension includes:
a first sub-extension, connected to one of the first protrusions opposite to the first sub-pixel; and
a second sub-extension, connected to one of the first protrusion opposite to the second sub-pixel, where a gap is present between the first sub-extension and the second sub-extension;
where the first sub-extension is parallel to the second sub-extension, and a width direction of the gap is perpendicular to an extending direction of the first sub-extension; or the first sub-extension is opposite to the second sub-extension, and a width direction of the gap is consistent with an extending direction of the first sub-extension.

In some exemplary embodiments of the present disclosure, a width of the gap is greater than or equal to 0.5 microns and less than or equal to 15 microns.

In some exemplary embodiments of the present disclosure, the display panel further includes:
a third film layer, provided on a side of the first film layer away from the display substrate, where the third film layer is provided with a first recess, the first recess has at least an opening facing the first film layer, the refractive index of the first film layer is greater than a refractive index of the third film layer, the refractive index of the second film layer is greater than the refractive index of the third film layer, the first extension is located within the first recess, and the first protrusion is located within the first recess.

In some exemplary embodiments of the present disclosure, the display panel includes:
a touch layer group provided on the light-emitting side of the display substrate, where the first film layer is a layer of the touch layer group farthest from the display substrate.

In some exemplary embodiments of the present disclosure, the touch layer group includes touch grid lines, and orthographic projections of the touch grid lines on the display substrate do not overlap with the sub-pixels; and
where the first film layer covers the display substrate; or where the first film layer includes a first part and a second part spaced apart from each other, an orthographic projection of the first part on the display substrate covers the sub-pixels, and the orthographic projections of the touch grid lines on the display substrate are located within an orthographic projection of the second part on the display substrate.

In some exemplary embodiments of the present disclosure, the display panel includes an encapsulation layer group provided on the light-emitting side of the display substrate, and the encapsulation layer group includes:
a first inorganic layer, being the first film layer;
an organic layer, provided on a side of the first inorganic layer away from the display substrate, where the organic layer is the third film layer, and the second film layer is provided between the first inorganic layer and the organic layer; and
a second inorganic layer, provided on a side of the organic layer away from the display substrate.

In some exemplary embodiments of the present disclosure, the display panel includes an encapsulation layer group provided on the light-emitting side of the display substrate, and the encapsulation layer group includes:
a first inorganic layer, including a base layer and a protruding layer, where the base layer is the first film layer, and the protruding layer is the second film layer;
an organic layer, provided on a side of the first inorganic layer away from the display substrate, where the organic layer is the third film layer; and
a second inorganic layer, provided on a side of the organic layer away from the display substrate.

In some exemplary embodiments of the present disclosure, the second film layer is provided on a side of the first film layer away from the display substrate, the third film layer is provided on a side of the second film layer away from the display substrate, and at least part of the third film layer is located between adjacent ones of the first protrusions, between the first protrusion and the first extension, and between adjacent ones of the first extensions, thereby forming the first recess on the third film layer.

In some exemplary embodiments of the present disclosure, a height of a side wall of the first protrusion in a third direction decreases as a distance from a center of the first protrusion on a first plane increases, a height of a side wall of the first extension in the third direction decreases as a distance from a center of the first extension on the first plane increases, the first plane is parallel to a surface of the display substrate close to the first film layer, and the third direction is perpendicular to the first plane.

In some exemplary embodiments of the present disclosure, the third film layer is provided on a side of the first film layer away from the display substrate, the first recess is a first via provided on the third film layer, the second film layer is provided on a side of the third film layer away from the display substrate, and at least part of the second film layer is located within the first via, thereby forming the first protrusion and the first extension.

In some exemplary embodiments of the present disclosure, a height of a side wall of the first protrusion in a third direction increases as a distance from a center of the first protrusion on a first plane increases, a height of a side wall of the first extension in the third direction increases as a distance from a center of the first protrusion on the first plane increases, the first plane is parallel to a surface of the display substrate close to the first film layer, and the third direction is perpendicular to the first plane.

In some exemplary embodiments of the present disclosure, the light modulation layer group further includes:
a fourth film layer, provided on a side of the third film layer away from the display substrate, where the fourth film layer is provided with a second recess, the second recess has an opening facing the first film layer, and a refractive index of the fourth film layer is equal to the refractive index of the third film layer; and
a fifth film layer, provided on a side of the second film layer away from the display substrate and is located within the second recess, where a refractive index of the fifth film layer is equal to the refractive index of the second film layer, the fifth film layer includes a plurality of second protrusions and a plurality of second extensions, orthographic projections of the second protrusions on the display substrate overlap with the sub-pixels, and orthographic projections of the second extensions on the display substrate do not overlap with the sub-pixels.

In some exemplary embodiments of the present disclosure, the orthographic projections of the first protrusions on the display substrate are located within the orthographic projections of the second protrusions on the display substrate, and the orthographic projections of the first extensions on the display substrate are located within the orthographic projections of the second extensions on the display substrate.

In some exemplary embodiments of the present disclosure, the second extensions are connected to the second protrusions.

In some exemplary embodiments of the present disclosure, the fourth film layer is provided on the side of the third film layer away from the display substrate, the second recess is a second via provided on the fourth film layer, the fifth film layer is provided on a side of the fourth film layer away from the display substrate, and at least part of the fifth film layer is located within the second via, thereby forming the second protrusions and the second extensions.

In some exemplary embodiments of the present disclosure, a height of a side wall of the second protrusion in a third direction increases as a distance from a center of the second protrusion on a first plane increases, a height of a side wall of the second extension in the third direction increases as a distance from a center of the second protrusion on the first plane increases, the first plane is parallel to a surface of the display substrate close to the first film layer, and the third direction is perpendicular to the first plane.

In some exemplary embodiments of the present disclosure, the fifth film layer is provided on the side of the second film layer away from the display substrate, the fourth film layer is provided on a side of the fifth film layer away from the display substrate, and at least part of the fourth film layer is located between adjacent ones of the second protrusions, between the second protrusion and the second extension, and between adjacent ones of the second extensions, thereby forming the second recess on the fourth film layer.

In some exemplary embodiments of the present disclosure, a height of a side wall of the second protrusion in a third direction decreases as a distance from a center of the second protrusion on a first plane increases, a height of a side wall of the second extension in the third direction decreases as a distance from a center of the second extension on the first plane increases, the first plane is parallel to a surface of the display substrate close to the first film layer, and the third direction is perpendicular to the first plane.

In some exemplary embodiments of the present disclosure, the display panel includes:
a cover plate, provided on the light-emitting side of the display substrate, where the cover plate includes a flat layer and a protruding structure layer, the flat layer is the first film layer, and the protruding structure layer is the second film layer.

In some exemplary embodiments of the present disclosure, a height of a side wall of the first protrusion in a third direction decreases as a distance from a center of the first protrusion on a first plane increases, a height of a side wall of the first extension in the third direction decreases as a distance from a center of the first extension on the first plane increases, the first plane is parallel to a surface of the display substrate close to the first film layer, and the third direction is perpendicular to the first plane.

In some exemplary embodiments of the present disclosure, the light modulation layer group includes a first group and a second group; the display panel includes an encapsulation layer group and a touch layer group, the encapsulation layer group is provided on the light-emitting side of the display substrate, and the touch layer group is provided on a side of the encapsulation layer group away from the display substrate; the encapsulation layer group includes:
a first inorganic layer, being the first film layer of the first group;
an organic layer, provided on a side of the first inorganic layer away from the display substrate, where the organic layer is the third film layer of the first group, and the second film layer of the first group is provided between the first inorganic layer and the organic layer; and
a second inorganic layer, provided on a side of the organic layer away from the first inorganic layer.

In some exemplary embodiments of the present disclosure, the light modulation layer group includes a first group and a second group; the display panel includes an encapsulation layer group and a touch layer group, the encapsulation layer group is provided on the light-emitting side of the display substrate, and the touch layer group is provided on a side of the encapsulation layer group away from the display substrate; the encapsulation layer group includes:
a first inorganic layer, including a base layer and a protruding layer, where the base layer is the first film layer of the first group, and the protruding layer is the second film layer of the first group;
an organic layer, provided on a side of the first inorganic layer away from the display substrate, where the organic layer is the third film layer of the first group; and
a second inorganic layer, provided on a side of the organic layer away from the display substrate.

In some exemplary embodiments of the present disclosure, the first film layer of the second group is a layer in the touch layer group farthest from the display substrate; or,
the display panel further includes a cover plate provided on a side of the touch layer group away from the display substrate, where the cover plate includes a flat layer and a protruding structure layer, the flat layer is the first film layer of the second group, and the protruding structure layer is the second film layer of the second group.

In some exemplary embodiments of the present disclosure, the light modulation layer group further includes a third group, the first film layer of the second group is a layer in the touch layer group farthest from the display substrate; the display panel further includes a cover plate provided on a side of the touch layer group away from the display substrate; where the cover plate includes a flat layer and a protruding structure layer, the flat layer is the first film layer of the third group, and the protruding structure layer is the second film layer of the third group.

According to another aspect of the present disclosure, a display device is provided, including: a display panel in any one of embodiments as described above.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. The accompanying drawings described below are only some embodiments of the present disclosure, and for those skilled in the art, other accompanying drawings can be obtained based on these accompanying drawings without creative work.

FIG. 1 is a schematic structural diagram of a display panel according to an exemplary embodiment of the present disclosure.

FIG. 2 is a schematic structural diagram of a display panel according to a first exemplary embodiment of the present disclosure.

FIG. 3 is a schematic diagram of light rays where light loss occurs.

FIG. 4 is a schematic top view of a sub-pixel and a second film layer according to a first exemplary embodiment.

FIG. 5 is a schematic top view of a sub-pixel and a second film layer according to a second exemplary embodiment.

FIG. 6 is a schematic top view of a sub-pixel and a second film layer according to a third exemplary embodiment.

FIG. 7 is a schematic top view of a sub-pixel and a second film layer according to a fourth exemplary embodiment.

FIG. 8 is a schematic top view of a sub-pixel and a second film layer according to a fifth exemplary embodiment.

FIG. 9 is a schematic top view of a sub-pixel and a second film layer according to a sixth exemplary embodiment.

FIG. 10 is a schematic diagram of the optical path of light refracted by the first protrusion and the first extension.

FIG. 11 is a schematic structural diagram of a display panel according to a second exemplary embodiment of the present disclosure.

FIG. 12 is a schematic structural diagram of a display panel according to a third exemplary embodiment of the present disclosure.

FIG. 13 is a schematic diagram of the optical path of light totally reflected by the first protrusion and the first extension.

FIG. 14 is a schematic structural diagram of a display panel according to a fourth exemplary embodiment of the present disclosure.

FIG. 15 is a schematic structural diagram of a display panel according to a fifth exemplary embodiment of the present disclosure.

FIG. 16 is a schematic structural diagram of a display panel according to a sixth exemplary embodiment of the present disclosure.

FIG. 17 is a schematic structural diagram of a display panel according to a seventh exemplary embodiment of the present disclosure.

FIG. 18 is a schematic structural diagram of a display panel according to an eighth exemplary embodiment of the present disclosure.

FIG. 19 is a schematic structural diagram of a display panel according to a ninth exemplary embodiment of the present disclosure.

FIG. 20 is a schematic structural diagram of a display panel according to a tenth exemplary embodiment of the present disclosure.

FIG. 21 is a schematic structural diagram of a display panel according to an eleventh exemplary embodiment of the present disclosure.

FIG. 22 is a schematic structural diagram of a display panel according to a twelfth exemplary embodiment of the present disclosure.

FIG. 23 is a schematic structural diagram of a display panel according to a thirteenth exemplary embodiment of the present disclosure.

FIG. 24 is a schematic structural diagram of a display panel according to a fourteenth exemplary embodiment of the present disclosure.

FIG. 25 is a schematic structural diagram of a display panel according to a fifteenth exemplary embodiment of the present disclosure.

FIG. 26 is a schematic structural diagram of a display panel according to a sixteenth exemplary embodiment of the present disclosure.

### DESCRIPTION OF REFERENCE NUMERALS ARE AS FOLLOWS

10. display substrate; 1. base substrate;
2. driving backplane; 21. light shielding layer; 22. buffer layer; 231. channel portion; 232. source; 233. drain; 24. gate insulating layer; 25. gate; 26. interlayer dielectric layer; 27. first connection conductor layer; 271. source connecting line; 272. drain connecting line; 28. planarization layer;
3. light-emitting substrate; 31. first electrode; 32. pixel definition layer; 33. light-emitting layer group; 34. second electrode; 35. sub-pixel; 351. first sub-pixel; 352. second sub-pixel; 35B. blue sub-pixel; 35G. green sub-pixel;
4. encapsulation layer group; 41. first inorganic layer; 411. base layer; 412. protruding layer; 42. organic layer; 43. second inorganic layer;
5. touch layer group; 51. barrier layer; 52. first touch layer; 53. touch insulating layer; 54. second touch layer; 55. protection layer; 56. touch grid line;
6. light modulation layer group; 61. first film layer; 611. first part; 612. second part; 62. second film layer; 621. first protrusion; 622. first extension; 6221. first sub-extension; 6222. second sub-extension; 6223. gap; 63. third film layer; 631. first recess; 64. fourth film layer; 641. second recess; 65. fifth film layer; 651. second protrusion; 652. second extension;
6a, first group; 6b, second group; 6c, third group;
8. polarizer; 9. cover plate; 91. flat layer; 92. protruding structure layer;
X, first direction; Y, second direction; Z, third direction.

### DETAILED DESCRIPTION

Exemplary embodiments will now be described more fully with reference to the accompanying drawings. However, exemplary embodiments can be implemented in a variety of forms and should not be construed as limited to the embodiments set forth herein. Rather, these embodiments are provided so that the present disclosure will be comprehensive and complete and fully convey the concepts of the exemplary embodiments to those skilled in the art. The same reference numerals in the drawings represent the same or similar structures, and thus their detailed description will be omitted. In addition, the drawings are only schematic illustrations of the present disclosure and are not necessarily drawn to scale.

Although relative terms such as “upper” and “lower” are used in this specification to describe the relative relationship of one component as illustrated to another, these terms are used in this specification only for convenience, such as according to the orientation of the examples described in the drawings. It is understood that if the illustrated device is turned upside down, the component described as “upper” will become the “lower” component. When a structure is “on” another structure, it may mean that the structure is formed integrally on the another structure, or that the structure is “directly” disposed on the another structure, or that the structure is “indirectly” disposed on the another structure through yet another structure.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of related objects.

In this application, unless otherwise clearly specified and limited, the term “connection” should be understood in a broad sense. For example, “connection” can be a fixed connection, a detachable connection, or an integral connection; it can refer to direct connection or indirect connection through an intermediate medium. The term “and/or” is just a description of the association relationship of the associated objects, indicating that there can be three relationships. For example, A and/or B can mean: A exists alone, both A and B exist, and B exists alone. In addition, the character “/” in this article generally indicates that the previous and next associated objects are in an “or” relationship.

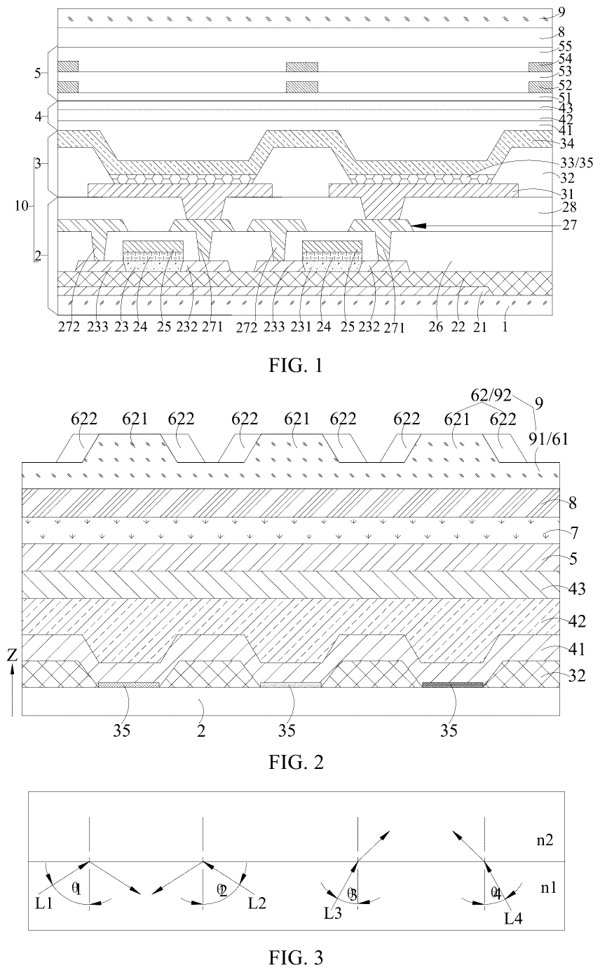

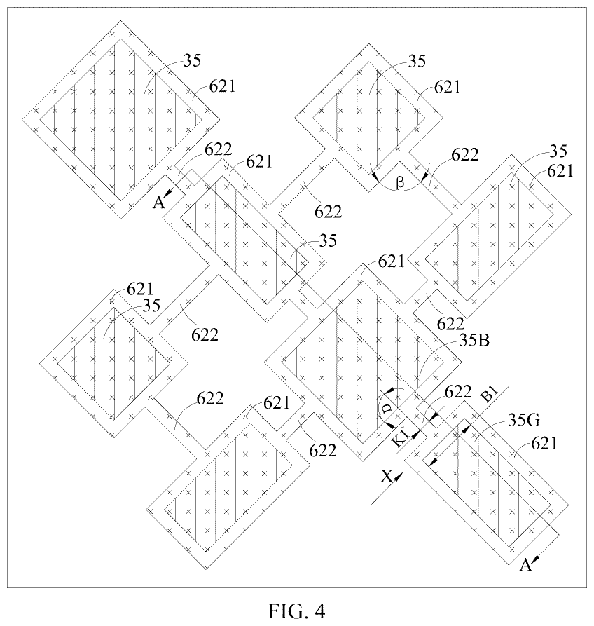

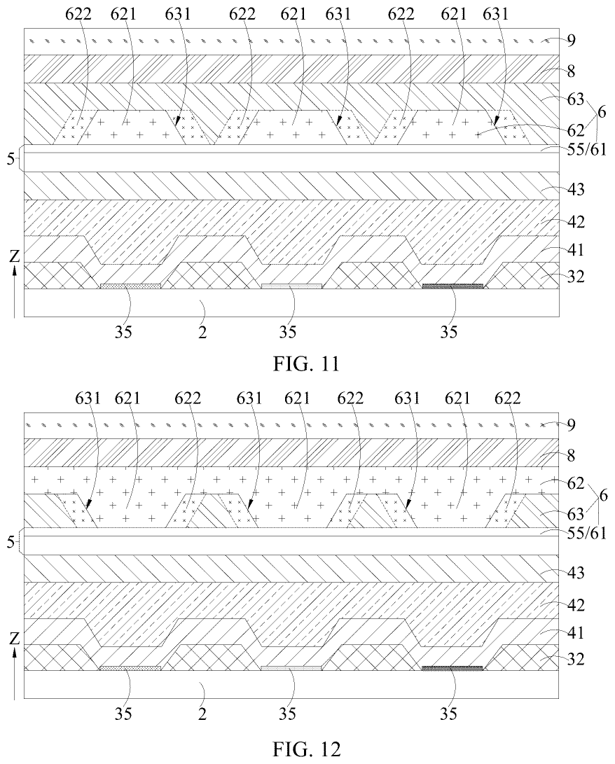

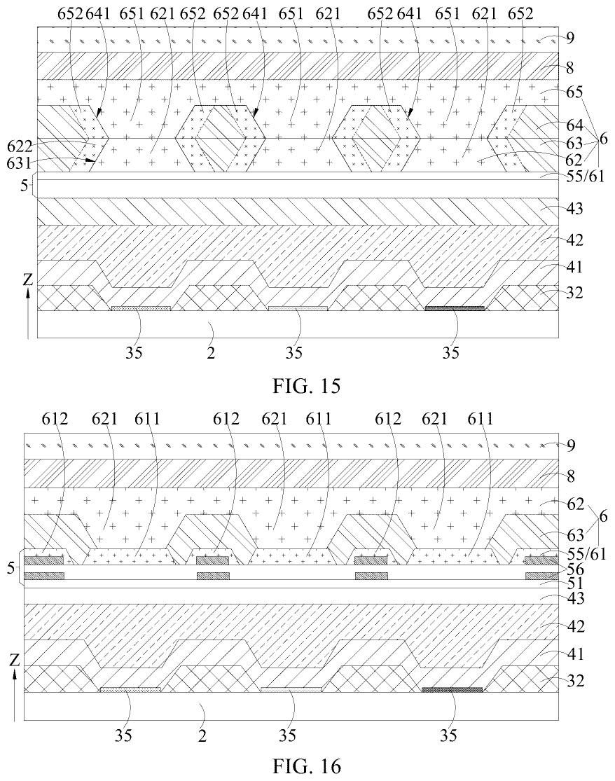

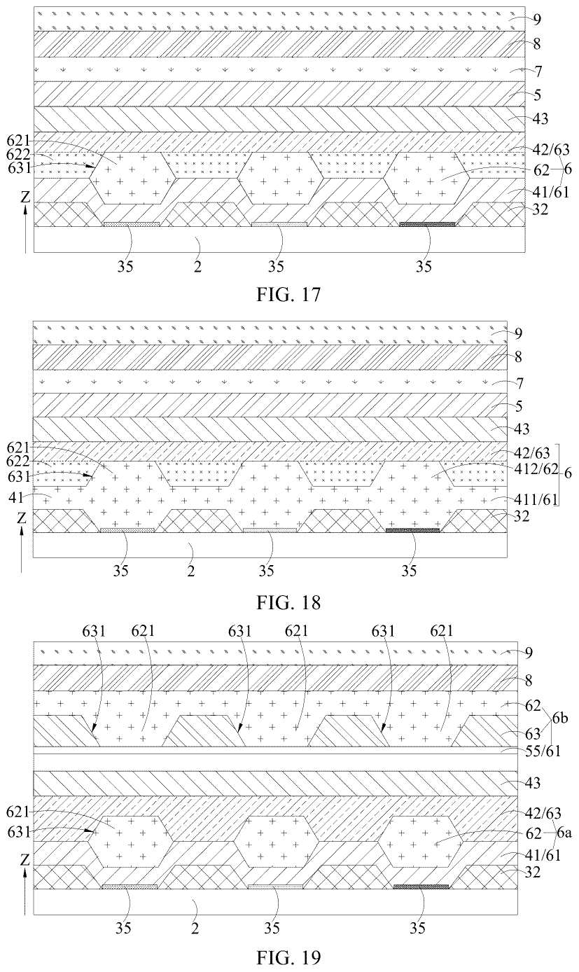

Exemplary embodiments of the present disclosure provide a display panel, as shown in FIG. 1 to FIG. 26, where FIG. 2, FIG. 11, FIG. 12, FIG. 14 to FIG. 26 are all cross-sectional schematic diagrams cut along A-A in FIG. 4, and FIG. 11, FIG. 12, FIG. 14, FIG. 15, FIG. 17 and FIG. 18 show the first extension 622 and the second extension 652, but since the first extension 622 and the second extension 652 are blocked, they are indicated by dotted lines. The first extension 622 and the second extension 652 in FIG. 11, FIG. 12, FIG. 14 and FIG. 15 are disconnected, and the first extension 622 in FIG. 17 and FIG. 18 is not disconnected. The specific structures of the first extension 622 and the second extension 652 can be reflected through the above drawings, so the first extension 622 and the second extension 652 are not reflected in FIG. 19 to FIG. 26.

The display panel may include a display substrate 10 and a light modulation layer group 6, the light modulation layer group 6 is arranged on the light-emitting side of the display substrate 10; the display substrate 10 may include a plurality of sub-pixels 35, and the light modulation layer group 6 may include a second film layer 62. The second film layer 62 is arranged on the light-emitting side of the display substrate 10, the second film layer 62 may include a plurality of first protrusions 621 and a plurality of first extensions 622, where the orthographic projection of the first protrusion 621 on the display substrate 10 overlaps with the sub-pixel 35, and the orthographic projection of the first extension 622 on the display substrate 10 does not overlap with the sub-pixel 35.

In the display panel according to the disclosure, the orthographic projection of the first protrusion 621 on the display substrate 10 overlaps with the sub-pixel 35. The first protrusion 621 can refract or reflect light with a larger inclination angle, so that the light is emitted from the front of the display panel, thereby improving the front light emission efficiency of the display panel. The orthographic projection of the first extension 622 on the display substrate 10 does not overlap with the sub-pixel 35. The first extension 622 can refract or reflect light with a larger inclination angle, so that the light is emitted from the front of the display panel, thereby further improving the front light emission efficiency of the display panel.

It should be noted that in this specification, the first direction X and the second direction Y are parallel to a surface of the display substrate 10 close to the first film layer 61. The first plane is parallel to the surface of the display substrate 10 close to the first film layer 61, that is, the first direction X and the second direction Y are parallel to the first plane. The third direction Z is perpendicular to the first plane, that is, the third direction Z is perpendicular to the first direction X and the second direction Y.

The display substrate 10 can be an OLED (Organic Electroluminescence Display) display substrate, a QLED (Quantum Dot Light Emitting Diodes) display substrate, or the like. The display substrate 10 has a light-emitting side and a non-light-emitting side, where the light-emitting side and the non-light-emitting side are arranged opposite to each other, and a picture can be displayed on the light-emitting side, the side displaying the picture being the display surface.

The following description will be made by taking an OLED display substrate as an example.

As shown in FIG. 1, the display panel may include a display substrate 10, which may include a base substrate 1, a driving backplane 2 and a light-emitting substrate 3. The driving backplane 2 is arranged on one side of the base substrate 1, and the light-emitting substrate 3 is arranged on the side of the driving backplane 2 away from the base substrate 1.

Referring to FIG. 1, the driving backplane 2 may include a plurality of driving circuits arranged in an array, the light-emitting substrate 3 may include a plurality of light-emitting devices arranged in an array, and the driving circuits may drive the light-emitting devices to emit light.

The material of the base substrate 1 may include an inorganic material, for example, the inorganic material may be glass, quartz or metal. The material of the base substrate 1 may also include an organic material, for example, the organic material may be a resin material such as polyimide, polycarbonate, polyacrylate, polyetherimide, polyethersulfone, polyethylene terephthalate and polyethylene naphthalate. The base substrate 1 may be formed by a plurality of material layers, for example, the base substrate 1 may include a plurality of substrate layers, and the material of the substrate layer may be any of the above materials. Alternatively, the base substrate 1 may also be provided as a single layer, which may be any of the above materials.

As shown in FIG. 1, a light shielding layer 21 may be provided on one side of the base substrate 1. Light incident from the base substrate 1 into the active layer may generate photogenerated carriers in the active layer, which in turn may have a significant impact on the characteristics of the thin film transistor, and ultimately affect the display quality of the display device. The light shielding layer 21 may shield the light incident from the base substrate 1, thereby avoiding affecting the characteristics of the thin film transistor and the display quality of the display device. Depending on the type of thin film transistor, the light shielding layer 21 may be omitted.

A buffer layer 22 may also be formed on the side of the light shielding layer 21 away from the base substrate 1. The buffer layer 22 serves to block water vapor and impurity ions in the base substrate 1 (especially organic materials), and serves to add hydrogen ions to the active layer formed subsequently. The buffer layer 22 is made of insulating material, which can insulate and isolate the light shielding layer 21 from the active layer. The buffer layer 22 may include silicon nitride, silicon oxide, or silicon oxynitride. Depending on the type of the base substrate 1 or process conditions, the buffer layer 22 may be omitted.

An active layer is provided on the side of the buffer layer 22 away from the base substrate 1. The active layer may include a channel portion 231 and conductor portions provided at both ends of the channel portion 231. One of the two conductor portions is a source 232 and the other is a drain 233. A gate insulating layer 24 is provided on the side of the active layer away from the base substrate 1. A gate 25 is provided on the side of the gate insulating layer 24. An interlayer dielectric layer 26 is provided on the side of the gate 25 away from the base substrate 1. A through hole is provided on the interlayer dielectric layer 26, and the through hole is connected to the conductor portion. A first connection conductor layer 27 is provided on the side of the interlayer dielectric layer 26 away from the base substrate 1. The first connection conductor layer 27 may include a source connection line 271 and a drain connection line 272. The source connection line 271 is connected to the source 232 through a via on the interlayer dielectric layer 26, and the drain connection line 272 is connected to the drain 233 through a via on the interlayer dielectric layer 26. A planarization layer 28 is provided on the side of the first connection conductor layer 27 away from the base substrate 1. A through hole is provided on the planarization layer 28, and the through hole is connected to the source connection line 271. The channel portion 231, the gate 25, the source 232 and the drain 233 form a thin film transistor.

In some other exemplary embodiments of the present disclosure, a passivation layer is provided on the side of the first connection conductor layer 27 away from the base substrate 1, and a via is also provided on the passivation layer; a second connection conductor layer is provided on the side of the passivation layer away from the base substrate 1, and the second connection conductor layer may include a second source connection line and/or a second drain connection line, where the second source connection line and the second drain connection line are correspondingly connected to the source connection line 271 and the drain connection line 272 through the vias on the passivation layer. Alternatively, a third connection conductor layer, a fourth connection conductor layer, and the like may further be provided as needed.

It should be noted that the thin film transistor described in this specification is a top-gate thin film transistor. In other exemplary embodiments of the present disclosure, the thin film transistor may also be a bottom-gate type or a dual-gate type, and its specific structure will not be described in detail here. Moreover, in the case of using thin film transistors with opposite polarities or when the current direction changes during circuit operation, the functions of the “source 232” and the “drain 233” are sometimes interchanged. Therefore, in this specification, the “source 232” and the “drain 233” may be interchanged.

Still referring to FIG. 1, a light-emitting substrate 3 is disposed on the side of the planarization layer away from the base substrate 1. The light-emitting substrate 3 may include a first electrode 31, a pixel definition layer 32, a light-emitting layer group 33 and a second electrode 34.

Specifically, the first electrode 31 is disposed on the side of the planarization layer away from the base substrate 1. The first electrode 31 is connected to the source 232 of the driving backplane 2 through a through hole. The first electrode 31 may be an anode (pixel electrode).

The pixel definition layer 32 is disposed on the side of the first electrode 31 away from the base substrate 1. An opening is disposed on the pixel definition layer 32. The opening is connected to the first electrode 31, so that at least part of the first electrode 31 is not covered by the pixel definition layer 32.

The light-emitting layer group 33 is disposed on the side of the pixel definition layer 32 away from the base substrate 1, and at least part of the light-emitting layer group 33 is located in the opening. The second electrode 34 is disposed on the side of the light-emitting layer group 33 away from the base substrate 1, and the second electrode 34 may be a cathode (common electrode). The light-emitting layer group 33 in an opening emits light to form a sub-pixel 35, so that the orthographic projection of the sub-pixel 35 on the base substrate 1 is the orthographic projection of the light-emitting layer group 33 in the opening on the base substrate 1, and the display substrate 10 may include a plurality of sub-pixels 35.

The light-emitting layer group 33 may include a hole injection layer, a hole transport layer, an organic light-emitting layer, an electron transport layer and an electron injection layer stacked in sequence, where the hole injection layer is in contact with the first electrode 31, and the electron injection layer is in contact with the second electrode 34. Alternatively, in other exemplary embodiments of the present disclosure, the light-emitting layer group 33 may only include a hole transport layer, a light-emitting layer and an electron transport layer, and the light-emitting layer group 33 may also be in other structures, and its specific structure may be provided as needed.

Holes are injected into the organic light-emitting layer from the first electrode 31 side, and electrons are injected into the organic light-emitting layer from the second electrode 34 side. Finally, the holes and electrons recombine in the organic light-emitting layer to generate excitons. When the generated excitons relax from the excited state to the ground state, the OLED emits visible light.

An encapsulation layer group 4 is provided on the side of the second electrode 34 away from the base substrate 1. As shown in FIG. 1, the encapsulation layer group 4 may be provided as a multilayer, and the encapsulation layer group 4 may include an organic layer 42 and an inorganic layer. Specifically, the encapsulation layer group 4 may include a first inorganic layer 41, an organic layer 42 provided on the side of the first inorganic layer 41 away from the base substrate 1, and a second inorganic layer 43 provided on the side of the organic layer 42 away from the base substrate 1. The materials of the first inorganic layer 41, the organic layer 42, and the second inorganic layer 43 are not described in detail here. Alternatively, the encapsulation layer group 4 may also include more layers or fewer layers.

In this exemplary embodiment, as shown in FIG. 1, a touch layer group 5 is provided on the side of the encapsulation layer group 4 away from the substrate 1. The touch layer group 5 may include a barrier layer 51, a first touch layer 52, a touch insulating layer 53, a second touch layer 54, and a protective layer 55. The barrier layer 51 is provided on the side of the encapsulation layer group 4 away from the substrate 1. The material of the barrier layer 51 may be a SiNx material. The first touch layer 52 is provided on the side of the barrier layer 51 away from the substrate 1. The first touch layer 52 may be a three-layer structure of Ti/Al/Ti, a three-layer structure of ITO/Ag/ITO, or the like. The touch insulating layer 53 is provided on the side of the first touch layer 52 away from the substrate 1. The material of the touch insulating layer 53 may be a SiNx material. The second touch layer 54 is provided on the side of the touch insulating layer 53 away from the substrate 1. The second touch layer 54 may be a three-layer structure of Ti/Al/Ti, ITO/Ag/ITO, or the like. The protective layer 55 is disposed on the side of the second touch layer 54 away from the base substrate 1, and the material of the protective layer 55 is PI (polyimide). Alternatively, the materials and structures of the above-mentioned film layers are only examples, and can be selected and arranged according to needs.

A polarizer 8 may be disposed on a side of the touch layer group 5 away from the display substrate 10, and a cover plate 9 may be disposed on a side of the polarizer 8 away from the display substrate 10.

After being emitted from the sub-pixel 34, the light will pass through multiple organic and inorganic layers with different refractive indices, and finally be emitted from the cover plate 9, thereby causing light loss in various modes.

As shown in FIG. 3, in particular, for light rays emitted from a high refractive index medium (n1) to a low refractive index medium (n2), when the inclination angle of the light rays is large, that is, when the incident angle (θ1, θ2) of the incident light rays is greater than or equal to the critical angle, these light rays will be totally reflected and cannot be emitted. Only when the inclination angle of the light rays is small, that is, when the incident angle (θ3, θ4) of the incident light rays is less than the critical angle, these light rays will be refracted and emitted into the low refractive index medium. The critical angle is calculated by arcsin (n2/n1), where n2 is the refractive index of the low refractive index medium and n1 is the refractive index of the high refractive index medium. Therefore, when n2=n1, the critical angle is 90 degrees; the closer n2 is to n1, the larger the critical angle is, and the larger the inclination angle of the incident light rays is, the total reflection will occur.

For example, since the refractive index of the cover plate 9 is greater than that of the air, total reflection will occur when the light is emitted from the cover plate 9 to the air, and the light loss is about 23%. Moreover, due to the metal loss of the first electrode 31, the light loss is about 4%; due to the surface plasma of the first electrode 31, the light loss is about 40%; from the sub-pixel 34 to the cover plate 9, there are also multiple organic layers and inorganic layers with different refractive indices, and the light loss is about 15%. Therefore, the light emitted from the cover plate 9 is only about 18%.

Referring to FIG. 2 to FIG. 26, in order to reduce the occurrence of total reflection of the light emitted from the high refractive index medium to the low refractive index medium, a light modulation layer group 6 is provided. Specifically, a second film layer 62 is provided on the first film layer 61 of the high refractive index medium, and the difference between the refractive index of the second film layer 62 and the refractive index of the first film layer 61 is less than or equal to 15% of the refractive index of the first film layer 61, that is, the refractive index of the second film layer 62 is basically the same as or close to the refractive index of the first film layer 61, so that total reflection does not occur at the interface between the second film layer 62 and the first film layer 61; or, even if there is total reflection, the critical angle of total reflection is large, and total reflection will only occur when the inclination of the incident light is large.

Referring to FIG. 2 and FIG. 4, some film layers in the driving backplane 2 and the light-emitting substrate 3 are omitted in FIG. 2, and FIG. 4 only shows the structural relationship between the sub-pixel 35 and the first protrusion 621 and the first extension 622 of the second film layer 62. The cover plate 9 may include a flat layer 91 and a protruding structure layer 92, where the flat layer 91 may be the first film layer 61, the protruding structure layer 92 may be the second film layer 62, and the protruding structure layer 92 may include a plurality of first protrusions 621 and a plurality of first extensions 622. The refractive index of the first film layer 61 is greater than or equal to 1.45 and less than or equal to 1.65, and the second film layer 62 may be formed by etching a thicker material layer of the cover plate 9, so the refractive index of the second film layer 62 is the same as that of the first film layer 61, that is, the refractive index of the second film layer 62 is greater than or equal to 1.45 and less than or equal to 1.65.

The specific structures of the first protrusion 621 and the first extension 622 are described below by taking the cover plate 9 as an example.

The first extension 622 may be connected to the first protrusion 621.

The orthographic projection of the first protrusion 621 on the display substrate 10 overlaps with the sub-pixel 35. For example, the edge line of the orthographic projection of the first protrusion 621 on the display substrate 10 may coincide with the edge line of the sub-pixel 35, or the orthographic projection of the first protrusion 621 on the display substrate 10 may cover and be larger than the sub-pixel 35; or a part of the orthographic projection of the first protrusion 621 on the display substrate 10 may overlap with a part of the sub-pixel 35; or the sub-pixel 35 may cover and be larger than the orthographic projection of the first protrusion 621 on the display substrate 10.

The shape of the orthographic projection of the first protrusion 621 on the display substrate 10 may be the same as the shape of the sub-pixel 35. For example, if the shape of the sub-pixel 35 is a rectangle, the orthographic projection of the first protrusion 621 on the display substrate 10 is also a rectangle; if the shape of the sub-pixel 35 is a circle, the orthographic projection of the first protrusion 621 on the display substrate 10 is also a circle; if the shape of the sub-pixel 35 is a hexagon, the orthographic projection of the first protrusion 621 on the display substrate 10 is also a hexagon. Alternatively, the shapes of the first protrusion 621 and the sub-pixel 35 may also be other shapes, which will not be described here. Alternatively, the shape of the orthographic projection of the first protrusion 621 on the display substrate 10 may be different from the shape of the sub-pixel 35.

The orthographic projection of the first extension 622 on the display substrate 10 does not overlap with the sub-pixel 35, that is, the orthographic projection of the first extension 622 on the display substrate 10 is located within the region between the sub-pixels 35.

The orthographic projection of the first extension 622 on the display substrate 10 may be a rectangle. Alternatively, the orthographic projection of the first extension 622 on the display substrate 10 may be a curve, a circle, an ellipse or various polygons.

In the case where one first extension 622 is provided between two adjacent sub-pixels 35, the width K1 of the first extension 622 in the first direction X is less than or equal to the length B1 of the shortest side, close to the first extension 622, of an adjacent sub-pixel 35, where the first direction X is parallel to the shortest side. Referring to FIG. 4, a first extension 622 is provided between the blue sub-pixel 35B and the green sub-pixel 35G, and the edge of the blue sub-pixel 35B close to the first extension 622 is longer than the edge of the green sub-pixel 35G close to the first extension 622. Therefore, the edge of the green sub-pixel 35G close to the first extension 622 is the shortest side, and the width K1 of the first extension 622 in the first direction X is less than or equal to the length B1 of the shortest side. In this way, multiple first extensions 622 are prevented from being connected as one, so that respective first extensions 622 form multiple side walls for reflection and refraction, thereby improving the front light extraction efficiency of the display panel.

Specifically, the width of the first extension 622 in the first direction X is greater than or equal to 0.5 micrometers and less than or equal to 30 micrometers. The above minimum value is the minimum value that can be achieved by the process and equipment. If the process and equipment allow, the above minimum value can be smaller. The above maximum value is determined according to the size of the sub-pixel 35 in order to avoid connecting multiple first extensions 622 into one piece.

Still referring to FIG. 4, when the sub-pixel 35 is a rectangle or various polygons, the extending direction of the first extension 622 intersects with the first edge of the adjacent sub-pixel 35 with the intersection angle α being greater than or equal to 45 degrees, where the first edge is the side edge of the sub-pixel 35 close to the first extension 622, and the intersection angle α here refers to an acute angle. Therefore, the maximum intersection angle α is 90 degrees. For example, the intersection angle is 50 degrees, 53 degrees, 61 degrees, 68 degrees, 70.5 degrees, 75 degrees, 78.8 degrees, 82.5 degrees, 86 degrees, 90 degrees, etc.

The extending direction of the first extension 622 is a direction from the first protrusion 621 to the first extension 622, that is, the extending direction of the first extension 622 is a direction in which the first extension 622 protrudes from the first protrusion 621.

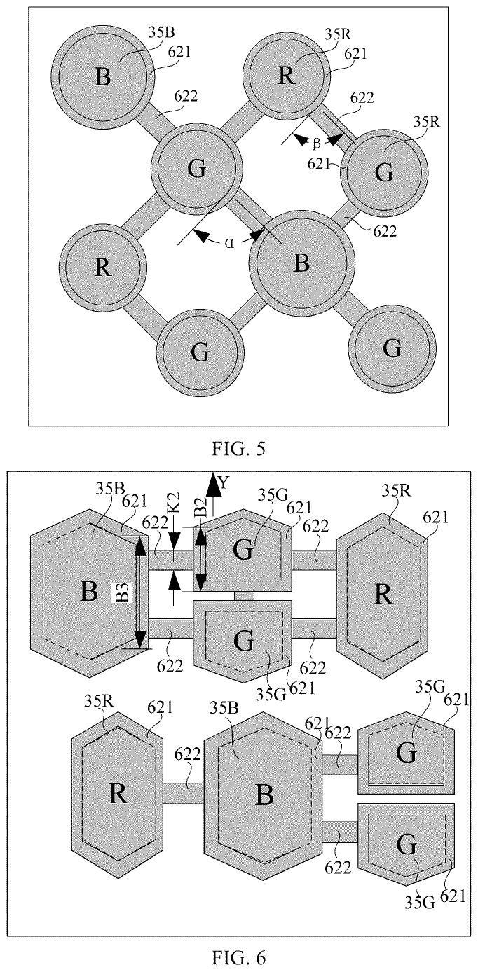

As shown in FIG. 5, when the sub-pixel 35 is circular or elliptical, the partial edge of the circle or ellipse close to the first extension 622 can be viewed as a short straight line, which is the first edge of the sub-pixel 35. Similarly, the intersection angle α between the extending direction of the first extension 622 and the first edge of the sub-pixel 35 is greater than or equal to 45 degrees. The intersection angle α here refers to an acute angle. Therefore, the maximum intersection angle α is 90 degrees. For example, the intersection angle is 50 degrees, 53 degrees, 61 degrees, 68 degrees, 70.5 degrees, 75 degrees, 78.8 degrees, 82.5 degrees, 86 degrees, 90 degrees, etc.

Such a configuration can prevent the first extension 622 from being unable to connect between two adjacent first protrusions 621, and also facilitate calculation and process preparation during design.

As shown in FIG. 6, the first extension 622 can be connected to the first protrusion 621, and one first extension 622 can be connected to one side edge of the first protrusion 621, or two first extensions 622 can be connected thereto. The number of first extensions 622 connected to one side edge of the first protrusion 621 can reach twenty.

Specifically, a first sideline of the first protrusion 621 is connected to a first extension 622, and a width of the first extension 622 in the second direction Y is less than or equal to a length of the first sideline, where the second direction Y is parallel to the first sideline. Referring to FIG. 6, a first sideline of the first protrusion 621, opposite to the green sub-pixel 35G, close to the blue sub-pixel 35B is connected to a first extension 622, and a width K2 of the first extension 622 in the second direction Y is less than or equal to a length B2 of the first sideline.

A first sideline of the first protrusion 621 is connected to at least two first extensions 622, and the sum of the widths of the at least two first extensions 622 in the second direction Y is less than or equal to the length B3 of the first sideline, where the second direction Y is parallel to the first sideline. Referring to FIG. 6, a first sideline of the first protrusion 621, opposite to the blue sub-pixel 35B, close to the green sub-pixel 35G is connected to two first extensions 622, and the sum of the widths 2K2 of the two first extensions 622 in the second direction Y is less than or equal to the length B3 of the first sideline.

Such a configuration avoids the plurality of first extensions 622 from being connected as one, so that respective first extensions 622 form a plurality of side walls for reflection or refraction, thereby improving the front light extraction efficiency of the display panel. Such a configuration also avoids the first extension 622 from occupying more side walls of the first protrusion 621, so that the side walls of the first protrusion 621 form a larger reflection surface or refraction surface, thereby improving the front light extraction efficiency of the display panel.

Further, as shown in FIG. 4, when the first protrusion 621 is a rectangle or various polygons, the first extension 622 is connected to the first sideline of the first protrusion 621, and the extending direction of the first extension 622 intersects with the first sideline, with the intersection angle β being greater than or equal to 45 degrees. The intersection angle β refers to an acute angle, so the maximum intersection angle β is 90 degrees. For example, the intersection angle is 50 degrees, 53 degrees, 61 degrees, 68 degrees, 70.5 degrees, 75 degrees, 78.8 degrees, 82.5 degrees, 86 degrees, 90 degrees, etc. The extending direction of the first extension 622 is the direction in which the first protrusion 621 points to the first extension 622, that is, the extending direction of the first extension 622 is the direction in which the first extension 622 protrudes from the first protrusion 621.

As shown in FIG. 5, when the first protrusion 621 is a circular or elliptical shape, the partial edge of the circular or elliptical shape close to the first extension 622 can be viewed as a short straight line, which is the first side line of the sub-pixel 35. Similarly, the intersection angle β between the extending direction of the first extension 622 and the first side line of the sub-pixel 35 is greater than or equal to 45 degrees. The intersection angle β here refers to an acute angle. Therefore, the maximum intersection angle β is 90 degrees. For example, the intersection angle is 50 degrees, 53 degrees, 61 degrees, 68 degrees, 70.5 degrees, 75 degrees, 78.8 degrees, 82.5 degrees, 86 degrees, 90 degrees, etc.

Such a configuration can prevent the first extension 622 from being unable to connect between two adjacent first protrusions 621, and also facilitate calculation and process preparation during design.

As shown in FIG. 6, the first extension 622 is connected between two adjacent first protrusions 621. One first extension 622 can be connected between two adjacent first protrusions 621, or two first extensions 622 can be connected therebetween. Alternatively, more first extensions 622 can be connected, and the number of first extensions 622 connected between two adjacent first protrusions 621 can reach twenty.

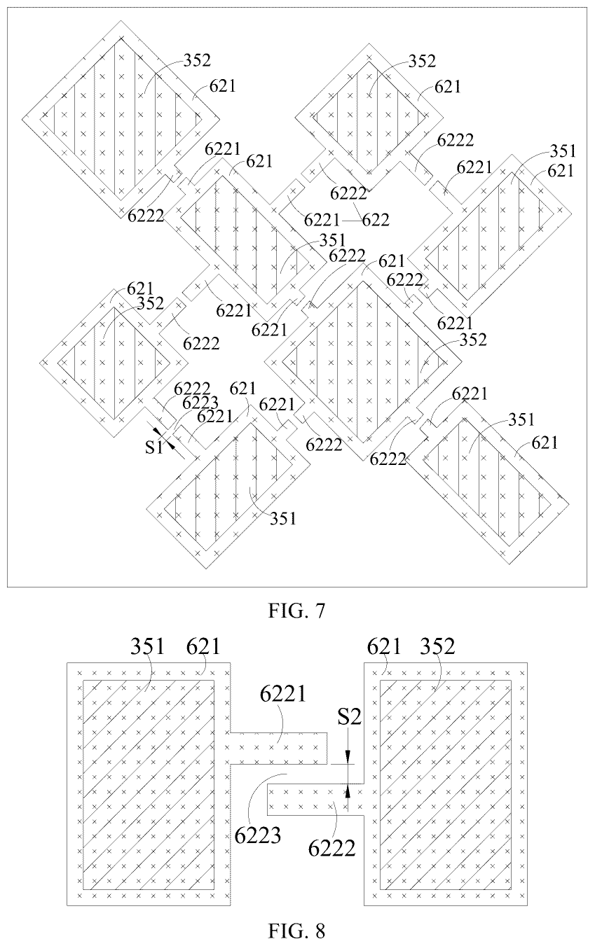

Further, as shown in FIG. 7, the first extension 622 connected between two adjacent first protrusions 621 may be disconnected. For example, two adjacent sub-pixels 35 include a first sub-pixel 351 and a second sub-pixel 352. The first extension 622 may include a first sub-extension 6221 and a second sub-extension 6222. The first sub-extension 6221 is connected to the first protrusion 621 opposite to the first sub-pixel 351. The second sub-extension 6222 is connected to the first protrusion 621 opposite to the second sub-pixel 352. A gap 6223 is provided between the first sub-extension 6221 and the second sub-extension 6222, and a width S1 of the gap 6223 is greater than or equal to 0.5 microns and less than or equal to 15 microns. For example, the width of the gap 6223 may be 0.8 microns, 1 micron, 1.5 microns, 1.75 microns, 2 microns, 2.46 microns, 2.8 microns, 3.1 microns, 3.81 microns, 4 microns, 5.5 microns, 6.75 microns, 8 microns, 9.46 microns, 10.8 microns, 11.1 microns, 12.81 microns, 13.8 microns, 14.1 microns, 14.81 microns, and the like.

The first sub-extension 6221 and the second sub-extension 6222 extend in the same direction and are arranged opposite to each other, for example, directly facing each other. The width S1 of the gap 6223 is consistent with the extending direction of the first sub-extension 6221.

Alternatively, as shown in FIG. 8, the extending directions of the first sub-extension 6221 and the second sub-extension 6222 are consistent, but the first sub-extension 6221 and the second sub-extension 6222 are not arranged directly facing each other. Instead, a part of the first sub-extension 6221 and a part of the second sub-extension 6222 are arranged parallel to each other. In this case, the width S2 of the gap 6223 is perpendicular to the extending direction of the first sub-extension 6221.

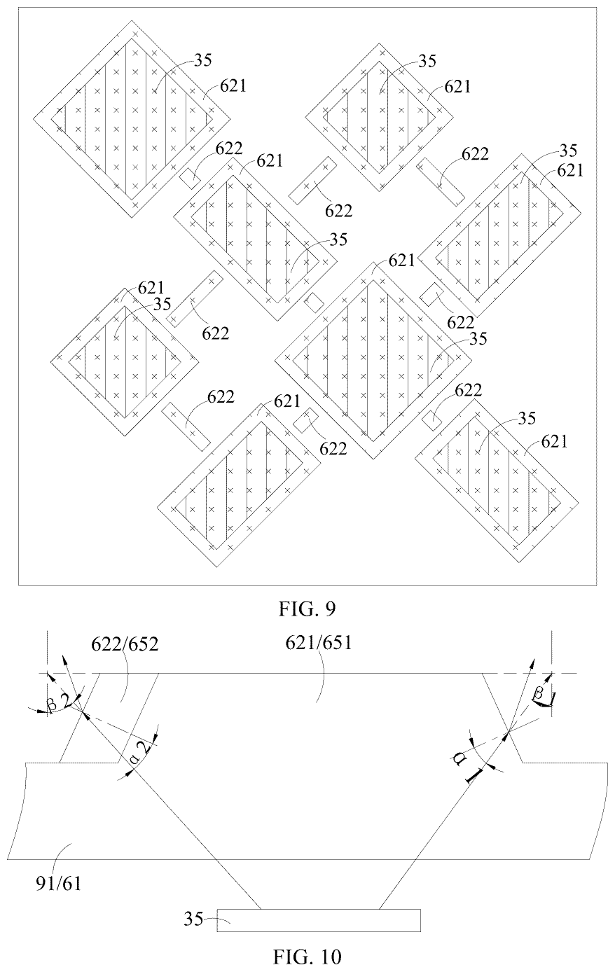

As shown in FIG. 9, the first extension 622 may not be connected to the first protrusion 621, that is, the first extension 622 may be arranged between two adjacent first protrusions 621, but is not connected to the first protrusions 621. Alternatively, the first extension 622 may not be arranged between two adjacent first protrusions 621.

Furthermore, referring to FIG. 2, the height of the side wall of the first protrusion 621 in the third direction Z decreases as the distance from the center of the first protrusion 621 on the first plane increases, that is, the side wall of the first protrusion 621 can be formed as an inclined surface, and the cross-sectional area of the first protrusion 621 parallel to the first plane decreases as the distance from the display substrate 10 increases. In other words, the first protrusion 621 is provided as a right truncated cone or a right prism, and the cross section of the first protrusion 621 perpendicular to the display substrate 10 is a right trapezoid.

The height of the side wall of the first extension 622 in the third direction Z decreases as the distance from the center of the first extension 622 on the first plane increases. That is, the side wall of the first extension 622 can be provided as an inclined surface, and the cross-sectional area of the first extension 622 parallel to the first plane decreases as the distance from the display substrate 10 increases. In other words, the first extension 622 is provided as a right prism, and the cross section of the first extension 622 perpendicular to the display substrate 10 is a right trapezoid.

After passing through the cover plate 9, the light is emitted to the air. The refractive index of the air is about 1, which is smaller than the refractive index of the cover plate 9. Therefore, the light with a larger inclination angle will be totally reflected in the cover plate 9 and cannot be emitted from the cover plate 9. As shown in FIG. 10, after the protruding structure layer 92 is formed on the cover plate 9, the light emitted from the sub-pixel 35 is emitted to the first protrusion 621. The incident angle of the central light is small and will not be totally reflected, and will be emitted through the cover plate 9. The incident angle al formed between the peripheral light with a larger inclination angle and the side wall of the first protrusion 621 is much smaller than the original incident angle β1, thereby avoiding total reflection. Instead, refraction is generated, so that the peripheral light with a larger inclination angle can also be emitted through the cover plate 9. Moreover, since the light is emitted from the optically dense medium into the optically sparse medium, the refraction angle is larger than the incident angle, so that the emitted light is offset toward the center position of the sub-pixel 35, thereby improving the front light extraction efficiency of the display panel. Peripheral light with a larger inclination angle is directed to the side wall of the first extension 622, and similarly these light rays are refracted, so that the peripheral light with a larger inclination angle can also be emitted through the cover plate 9. Moreover, since the light is emitted from the optically dense medium into the optically sparse medium, the refraction angle is larger than the incident angle, so that the emitted light is offset toward the center position of the sub-pixel 35, thereby improving the front light extraction efficiency of the display panel.

The structures of the first protrusion 621 and the first extension 622 are described in detail above. The positions of the first film layer 61 and the second film layer 62 are described below.

In the case where the light modulation layer group 6 adopts a cover plate 9, the light modulation layer group 6 may include a first film layer 61 and a second film layer 62. As shown in FIG. 11 to FIG. 20, in the case where the light modulation layer group 6 is arranged inside the display panel, the display panel may further include a third film layer 63. The third film layer 63 is arranged on the side of the first film layer 61 away from the display substrate 10. A first recess 631 is arranged on the third film layer 63. The first recess 631 has at least an opening toward the first film layer 61. The refractive index of the first film layer 61 is greater than that of the third film layer 63. The refractive index of the second film layer 62 is greater than that of the third film layer 63. The first extension 622 is located in the first recess 631. The first protrusion 621 is located in the first recess 631.

Since the refractive index of the first film layer 61 is greater than that of the third film layer 63, the light with a large inclination angle emitted from the first film layer 61 to the third film layer 63 may be totally reflected in the first film layer 61 and cannot be emitted. The refractive index of the second film layer 62 is greater than that of the third film layer 63, that is, the refractive index of the second film layer 62 is the same as or close to that of the first film layer 61. Therefore, when the light is emitted from the first film layer 61 to the second film layer 62, the light will hardly be totally reflected.

In some exemplary embodiments, as shown in FIG. 11, the first film layer 61 may be a layer of the touch layer group 5 that is farthest from the display substrate 10. For example, the first film layer 61 is the protective layer 55 in the touch layer group 5, and the refractive index of the protective layer 55 is relatively large, which is greater than or equal to 1.8 and less than or equal to 1.9. The second film layer 62 is disposed on the side of the first film layer 61 away from the display substrate 10, and the refractive index of the second film layer 62 is greater than or equal to 1.65 and less than or equal to 1.85.

Specifically, the third film layer 63 is disposed on the side of the second film layer 62 away from the display substrate 10, and parts of the third film layer 63 are located between adjacent first protrusions 621, between the first protrusion 621 and the first extension 622, and between adjacent first extensions 622, so as to form the first recesses 631 on the third film layer 63, with the openings of the first recesses 631 facing the display substrate 10. The third film layer 63 may be completely attached to the second film layer 62 and the first film layer 61, so the structure of the first recesses 631 is compatible with the structure of the first protrusion 621 and the first extension 622, which will not be repeated here. The refractive index of the third film layer 63 is greater than or equal to 1.45 and less than or equal to 1.55.

Moreover, the height of the side wall of the first protrusion 621 in the third direction Z decreases as the distance from the center of the first protrusion 621 on the first plane increases, that is, the side wall of the first protrusion 621 can be provided as an inclined surface. The cross-sectional area of the first protrusion 621 parallel to the first plane decreases as the distance from the display substrate 10 increases. That is, the first protrusion 621 is provided as a right truncated cone or a right prism, and the cross section of the first protrusion 621 perpendicular to the display substrate 10 is a right trapezoid. As shown in FIG. 10, the light emitted from the sub-pixel 35 hits the first protrusion 621. The incident angle of the central light is small without occurring total reflection, so it will pass through the second film layer 62 to the third film layer 63. The incident angle α1 formed between the peripheral light with a larger inclination angle and the first protrusion 621 is much smaller than the original incident angle β1, thereby avoiding total reflection and instead causing refraction, so that the peripheral light with a larger inclination angle can also pass through the first protrusion 621 to the third film layer 63. Moreover, since the light is emitted from the optical dense medium into the optical sparse medium, the refraction angle is larger than the incident angle, so that the emitted light is offset toward the center of the sub-pixel 35, thereby improving the light extraction efficiency of the display panel.

The height of the side wall of the first extension 622 in the third direction Z decreases as the distance from the center of the first extension 622 on the first plane increases. That is, the side wall of the first extension 622 can be provided as an inclined surface. The cross-sectional area of the first extension 622 parallel to the first plane decreases as the distance from the display substrate 10 increases. That is, the first extension 622 is provided as a right prism, and the cross section of the first extension 622 perpendicular to the display substrate 10 is a right trapezoid. Since the orthographic projection of the first extension 622 on the display substrate 10 is located in the area between adjacent sub-pixels 35, the inclination angle of the light emitted from the sub-pixel 35 to the first extension 622 is larger. If the first extension 622 is not provided, these light rays will all be totally reflected and cannot be emitted. After the first extension 622 is provided, the light rays are emitted to the side wall of the first extension 622. Similarly, as shown in FIG. 10, the incident angle α2 formed between these light rays and the first protrusion 621 is much smaller than the original incident angle β2, thereby avoiding total reflection, so that the peripheral light rays with larger inclination angles can also pass through the first extension 622 to the third film layer 63. Moreover, since the light is emitted from the optically dense medium to the optically sparse medium, the refraction angle is larger than the incident angle, so that the emitted light is offset toward the center position of the sub-pixel 35, thereby further improving the light extraction efficiency of the display panel.

It should be noted that the side wall of the first extension 622 refers to the side wall of the other side of the first extension 622 that is not connected to the first protrusion 621. For example, when the first extension 622 is provides as a strip, the side wall of the first extension 622 refers to the side wall of the other three sides of the first extension 622 that are not connected to the first protrusion 621. The side of the first extension 622 that is connected to the first protrusion 621 will not form a separate side wall of the first extension 622.

Moreover, since the side wall of the first protrusion 621 is arranged at an angle, the above-mentioned orthographic projection of the first protrusion 621 on the base substrate 1 refers to the orthographic projection of the top surface of the first protrusion 621 on the base substrate 1, that is, the orthographic projection of the smallest surface of the first protrusion 621 on the base substrate 1.

Referring to FIG. 12, the first film layer 61 may be a layer of the touch layer group 5 that is farthest from the display substrate 10. For example, the first film layer 61 is the protective layer 55 in the touch layer group 5, and the refractive index of the protective layer 55 is relatively large, which is greater than or equal to 1.8 and less than or equal to 1.9.

The third film layer 63 is disposed on the side of the first film layer 61 away from the display substrate 10, and a first via is disposed on the third film layer 63. The first recess 631 is the first via disposed on the third film layer 63. Accordingly, the first recess 631 has an opening not only toward the display substrate 10 but also toward the cover plate 9. The refractive index of the third film layer 63 is greater than or equal to 1.45 and less than or equal to 1.55.

The second film layer 62 is disposed on the side of the third film layer 63 away from the display substrate 10, and a part of the second film layer 62 is located in the first via to form the first protrusion 621 and the first extension 622. The refractive index of the second film layer 62 is greater than or equal to 1.65 and less than or equal to 1.85.

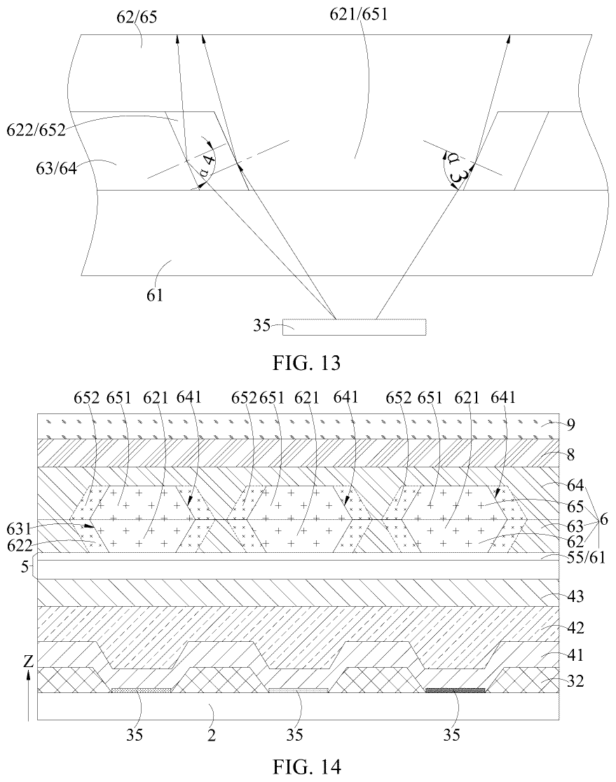

In this case, the height of the side wall of the first protrusion 621 in the third direction Z increases as the distance from the center of the first protrusion 621 on the first plane increases, that is, the side wall of the first protrusion 621 can be provided as an inclined surface. The cross-sectional area of the first protrusion 621 parallel to the first plane increases as the distance from the display substrate 10 increases. That is, the first protrusion 621 is provided as an inverted truncated cone or an inverted prism, and the cross section of the first protrusion 621 perpendicular to the display substrate 10 is an inverted trapezoid. As shown in FIG. 13, the light emitted from the sub-pixel 35 is emitted to the first protrusion 621. The incident angle of the central light is small without occurring total reflection, and it will be emitted directly through the first film layer 61 and the second film layer 62. The incident angle α3 of the peripheral light with a large inclination angle is large and total reflection will occur on the side of the first protrusion 621. The light after total reflection is emitted almost perpendicular to the display substrate 10, that is, the first protrusion 621 can adjust the incident angle of the peripheral light with a large inclination angle, so that the peripheral light with a large inclination angle can also be emitted through the first protrusion 621, thereby improving the light extraction efficiency of the display panel. The light is deflected to a direction close to the normal viewing angle, so as to improve the light extraction gain of the normal viewing angle.

The height of the side wall of the first extension 622 in the third direction Z increases as the distance from the center of the first protrusion 621 on the first plane increases. That is, the side wall of the first extension 622 can be provided as an inclined surface. The cross-sectional area of the first extension 622 parallel to the first plane increases as the distance from the display substrate 10 increases. That is, the first extension 622 is provided as an inverted prism, and the cross section of the first extension 622 perpendicular to the display substrate 10 is an inverted trapezoid. Since the orthographic projection of the first extension 622 on the display substrate 10 is located in the area between the sub-pixels 35, the inclination angle of the light emitted from the sub-pixel 35 to the position of the first extension 622 is relatively large. If the first extension 622 is not provided, these light rays will all be totally reflected and cannot be emitted. After the first extension 622 is provided, the light rays are emitted to the side wall of the extension. Similarly, as shown in FIG. 13, these light rays with a larger incident angle α4 will be totally reflected on the side of the first extension 622, and the light rays after total reflection are emitted almost perpendicular to the display substrate 10. In other words, the first extension 622 can adjust the incident angle of the peripheral light rays with a larger inclination angle, so that the peripheral light rays can also be emitted through the first extension 622, thereby improving the light extraction efficiency of the display panel. The light rays are deflected to a direction close to the normal viewing angle, and the light extraction gain of the normal viewing angle is improved.

The third film layer 63 is completely attached to the second film layer 62 and the first film layer 61, so the structure of the first recess 631 is compatible with the structure of the first protrusion 621 and the first extension 622, which will not be repeated here.

Referring to FIG. 14 and FIG. 15, in the third direction Z, the height of the third film layer 63 is the same as the height of the second film layer 62, that is, the third film layer 63 has no part disposed on the second film layer 62, and the second film layer 62 has no part disposed on the third film layer 63.

Moreover, the light modulation layer group 6 may further include a fourth film layer 64 and a fifth film layer 65. At least part of the fourth film layer 64 is disposed on the side of the second film layer 62 away from the display substrate 10, a second recess 641 is disposed on the fourth film layer 64, the second recess 641 has an opening toward the first film layer 61, and the refractive index of the fourth film layer 64 may be equal to the refractive index of the third film layer 63. At least part of the fifth film layer 65 is disposed on the side of the second film layer 62 away from the display substrate 10 and is located in the second recess 641, the refractive index of the fifth film layer 65 may be equal to the refractive index of the second film layer 62, and the fifth film layer 65 may include a plurality of second protrusions 651 and a plurality of second extensions 652.

The orthographic projection of the second protrusion 651 on the display substrate 10 overlaps with the sub-pixel 35. For example, the edge line of the orthographic projection of the second protrusion 651 on the display substrate 10 may coincide with the edge line of the sub-pixel 35, or the orthographic projection of the second protrusion 651 on the display substrate 10 covers and is larger than the sub-pixel 35; or a part of the orthographic projection of the second protrusion 651 on the display substrate 10 overlaps with a part of the sub-pixel 35; or the sub-pixel 35 covers and is larger than the orthographic projection of the second protrusion 651 on the display substrate 10.

The shape of the orthographic projection of the second protrusion 651 on the display substrate 10 may be the same as the shape of the sub-pixel 35. For example, if the shape of the sub-pixel 35 is a rectangle, the orthographic projection of the second protrusion 651 on the display substrate 10 is also a rectangle; if the shape of the sub-pixel 35 is a circle, the orthographic projection of the second protrusion 651 on the display substrate 10 is also a circle; if the shape of the sub-pixel 35 is a hexagon, the orthographic projection of the second protrusion 651 on the display substrate 10 is also a hexagon. Alternatively, the shapes of the second protrusion 651 and the sub-pixel 35 may also be other shapes, which will not be elaborated here. Alternatively, the shape of the orthographic projection of the second protrusion 651 on the display substrate 10 may be different from the shape of the sub-pixel 35.

The orthographic projection of the second extension 652 on the display substrate 10 does not overlap with the sub-pixel 35, that is, the orthographic projection of the second extension 652 on the display substrate 10 is located in the region between the sub-pixels 35.

The orthographic projection of the second extension 652 on the display substrate 10 may be provided as a rectangle. Alternatively, the orthographic projection of the second extension 652 on the display substrate 10 may be provided as a curve, a circle, an ellipse or various polygons.

Further, the orthographic projection of the first protrusion 621 on the display substrate 10 is located within the orthographic projection of the second protrusion 651 on the display substrate 10. For example, the edge line of the orthographic projection of the first protrusion 621 on the display substrate 10 may coincide with the edge line of the orthographic projection of the second protrusion 651 on the display substrate 10; or, the orthographic projection of the second protrusion 651 on the display substrate 10 may cover and be larger than the orthographic projection of the first protrusion 621 on the display substrate 10.

The orthographic projection of the first extension 622 on the display substrate 10 is located within the orthographic projection of the second extension 652 on the display substrate 10. For example, the edge line of the orthographic projection of the first extension 622 on the display substrate 10 may coincide with the edge line of the orthographic projection of the second extension 652 on the display substrate 10; or, the orthographic projection of the second extension 652 on the display substrate 10 may cover and be larger than the orthographic projection of the first extension 622 on the display substrate 10.

Such an arrangement enables the first protrusion 621 and the first extension 622 as well as the second protrusion 651 and the second extension 652 to be manufactured and formed by using the same mask plate, thereby reducing the process cost.

Alternatively, in some other exemplary embodiments of the present disclosure, the orthographic projection of the first extension 622 on the display substrate 10 may not overlap with the orthographic projection of the second extension 652 on the display substrate 10; or, a part of the orthographic projection of the first extension 622 on the display substrate 10 overlaps with a part of the orthographic projection of the second extension 652 on the display substrate 10.

As shown in FIG. 15, the specific structure of the second film layer 62 is the same as that of the second film layer 62 shown in FIG. 11, and the height of the third film layer 63 is the same as that of the second film layer 62, that is, the third film layer 63 has no part disposed on the second film layer 62. The fourth film layer 64 is disposed on the side of the third film layer 63 away from the display substrate 10, and a second via is disposed on the fourth film layer 64, and the second recess 641 is the second via disposed on the fourth film layer 64. Accordingly, the second recess 641 has an opening not only toward the display substrate 10, but also toward the cover plate 9. The refractive index of the fourth film layer 64 may be equal to the refractive index of the third film layer 63, that is, the refractive index of the fourth film layer 64 is greater than or equal to 1.45 and less than or equal to 1.55.

The fifth film layer 65 is disposed on the side of the fourth film layer 64 away from the display substrate 10, and a part of the fifth film layer 65 is located in the second via, thereby forming the second protrusion 651 and the second extension 652. The refractive index of the fifth film layer 65 is equal to the refractive index of the second film layer 62, that is, the refractive index of the fifth film layer 65 is greater than or equal to 1.65 and less than or equal to 1.85. The second extension 652 can be connected to the second protrusion 651, and alternatively, the second extension 652 may not be connected to the second protrusion 651. The specific structure of the second protrusion 651 and the second extension 652 can be the same as the specific structure of the first protrusion 621 and the first extension 622, which will not be repeated here.

The height of the side wall of the second protrusion 651 in the third direction Z increases as the distance from the center of the second protrusion 651 on the first plane increases, that is, the side wall of the second protrusion 651 can be provided as an inclined surface. The cross-sectional area of the second protrusion 651 parallel to the first plane increases as the distance from the display substrate 10 increases. That is, the first protrusion 621 is provided as an inverted truncated cone or an inverted prism, and the cross section of the first protrusion 621 perpendicular to the display substrate 10 is an inverted trapezoid. Similarly, as shown in FIG. 13, when the light emitted from the sub-pixel 35 hits the second protrusion 651, the incident angle of the central light is small without occurring total reflection, and it will be emitted directly through each film layer. The incident angle α3 of the peripheral light with a larger inclination angle is large and total reflection will occur on the side of the second protrusion 651, and the light after total reflection is emitted almost perpendicular to the display substrate 10. In other words, the second protrusion 651 can adjust the incident angle of the peripheral light with a larger inclination angle, so that the peripheral light can also be emitted through the second protrusion 651, thereby improving the light extraction efficiency of the display panel. The light can be deflected to a direction close to the normal viewing angle, so as to improve the light extraction gain of the normal viewing angle.

The height of the side wall of the second extension 652 in the third direction Z increases as the distance from the center of the second protrusion 651 on the first plane increases. That is, the side wall of the second extension 652 can be provided as an inclined surface. The cross-sectional area of the second extension 652 parallel to the first plane increases as the distance from the display substrate 10 increases. That is, the second extension 652 is provided as an inverted prism, and the cross-section of the second extension 652 perpendicular to the display substrate 10 is an inverted trapezoid. Since the orthographic projection of the second extension 652 on the display substrate 10 is located in the area between the sub-pixels 35, the inclination angle of the light emitted from the sub-pixel 35 to the position of the second extension 652 is relatively large. If the second extension 652 is not provided, these light rays will all be totally reflected and cannot be emitted. After the second extension 652 is provided, the light rays are emitted to the side wall of the extension. Similarly, as shown in FIG. 13, the light rays with a large incident angle α4 will be totally reflected on the side of the second extension 652, and the light rays after total reflection are emitted almost perpendicular to the display substrate 10. In other words, the second extension 652 can adjust the incident angle of the peripheral light rays with a large inclination angle, so that the peripheral light rays can also be emitted through the second extension 652, thereby improving the light extraction efficiency of the display panel. The light rays are deflected to a direction close to the normal viewing angle, and the light extraction gain of the normal viewing angle is improved.

The fourth film layer 64 is completely attached to the second film layer 62 and the fifth film layer 65, so the structure of the second recess 641 is compatible with the structures of the second protrusion 651 and the second extension 652, which will not be repeated here.

As shown in FIG. 14, the specific structure of the third film layer 63 is the same as the specific structure of the third film layer 63 shown in FIG. 12, and the height of the third film layer 63 is the same as the height of the second film layer 62, that is, the second film layer 62 has no part disposed on the third film layer 63. The fifth film layer 65 is disposed on the side of the second film layer 62 away from the display substrate 10, and the refractive index of the fifth film layer 65 is equal to the refractive index of the second film layer 62, that is, the refractive index of the fifth film layer 65 is greater than or equal to 1.65 and less than or equal to 1.85. The fifth film layer 65 may include the second protrusion 651 and the second extension 652, where the second extension 652 may be connected to the second protrusion 651, and alternatively, the second extension 652 may not be connected to the second protrusion 651. The specific structure of the second protrusion 651 and the second extension 652 may be the same as the specific structure of the first protrusion 621 and the first extension 622, which will not be repeated here.

The fourth film layer 64 is arranged on the side of the fifth film layer 65 away from the display substrate 10, and parts of the fourth film layer 64 are located between adjacent second protrusions 651, between the second protrusion 651 and the second extension 652, and between adjacent second extensions 652, so as to form the second recess 641 on the fourth film layer 64, with the opening of the second recess 641 facing the display substrate 10.

The height of the side wall of the second protrusion 651 in the third direction Z decreases as the distance from the center of the second protrusion 651 on the first plane increases, that is, the side wall of the second protrusion 651 can be provided as an inclined surface. The cross-sectional area of the second protrusion 651 parallel to the first plane decreases as the distance from the display substrate 10 increases. That is, the second protrusion 651 is provided as a right truncated cone or a right prism, and the cross section of the second protrusion 651 perpendicular to the display substrate 10 is a right trapezoid. As shown in FIG. 10, the light emitted from the sub-pixel 35 hits the second protrusion 651. The incident angle of the central light is small without occurring total reflection, so it will be emitted through each film layer. The incident angle α1 formed between the peripheral light with a larger inclination angle and the second protrusion 651 is much smaller than the original incident angle β1, thereby avoiding total reflection and instead causing refraction, so that the peripheral light with a larger inclination angle can also be emitted through the second protrusion 651. Moreover, since the light is emitted from the optically dense medium into the optically sparse medium, the refraction angle is larger than the incident angle, so that the emitted light is offset toward the center of the sub-pixel 35, thereby improving the light extraction efficiency of the display panel.

The height of the side wall of the second extension 652 in the third direction Z decreases as the distance from the center of the second extension 652 on the first plane increases, that is, the side wall of the second extension 652 can be provided as an inclined surface. The cross-sectional area of the second extension 652 parallel to the first plane decreases as the distance from the display substrate 10 increases. That is, the second extension 652 is provided as a right prism, and the cross section of the second extension 652 perpendicular to the display substrate 10 is a right trapezoid. Since the orthographic projection of the second extension 652 on the display substrate 10 is located in the area between the sub-pixels 35, the inclination angle of the light emitted from the sub-pixel 35 to the position of the second extension 652 is larger. If the second extension 652 is not provided, these light rays will all be totally reflected and cannot be emitted. After the second extension 652 is provided, the light rays are emitted to the side wall of the second extension 652. Similarly, as shown in FIG. 10, the incident angle α2 formed between these light rays and the second protrusion 651 is much smaller than the original incident angle β2, thereby avoiding total reflection and instead generating refraction, so that the peripheral light rays with larger inclination angles can also be emitted through the second extension 652. Moreover, since the light rays are emitted from the optically dense medium into the optically sparse medium, the refraction angle is larger than the incident angle, so that the emitted light rays are offset toward the center position of the sub-pixel 35, thereby improving the light extraction efficiency of the display panel.

The touch layer group 5 may include a touch grid line 56, which is formed by the first touch layer 52 and the second touch layer 54. The orthographic projection of the touch grid line 56 on the display substrate 10 does not overlap with the sub-pixel 35, thereby preventing the touch grid line 56 from blocking the light emitted by the sub-pixel 35. The first film layer 61 in FIG. 2 and FIG. 11-FIG. 15 covers the display substrate, that is, the first film layer 61 is provided as a whole layer. As shown in FIG. 16, the first film layer 61 may not be provided as a whole layer, and the first film layer 61 may include a first part 611 and a second part 612 that are spaced apart, where the orthographic projection of the first part 611 on the display substrate 10 covers the sub-pixel 35, and the orthographic projection of the touch grid line 56 on the display substrate 10 is located within the orthographic projection of the second part 612 on the display substrate 10, so that the second part 612 can protect the second touch layer 54 and prevent the second touch layer 54 from being oxidized.

As shown in FIG. 17 and FIG. 18, the light modulation layer group may also be provided in the encapsulation layer group. Specifically, as shown in FIG. 17, the encapsulation layer group 4 may include a first inorganic layer 41, an organic layer 42, and a second inorganic layer 43 which are stacked in sequence. The first inorganic layer 41 is closer to the display substrate 10 than the second inorganic layer 43. The first inorganic layer 41 may be the first film layer 61. The refractive index of the first inorganic layer 41 is greater than or equal to 1.75 and less than or equal to 1.95. The organic layer 42 is provided on the side of the first inorganic layer 41 away from the display substrate 10, the organic layer 42 is the third film layer 63, and the refractive index of the organic layer 42 is greater than or equal to 1.45 and less than or equal to 1.55. Therefore, the refractive index of the organic layer 42 is less than the refractive index of the first inorganic layer 41. The light from the first inorganic layer 41 to the organic layer 42 is from a high refractive index medium to a low refractive index medium, and the light with a large incident angle will be totally reflected, resulting in a large amount of waveguide light loss. The second film layer 62 is disposed between the first inorganic layer 41 and the organic layer 42, and the refractive index of the second film layer 62 is greater than or equal to 1.65 and less than or equal to 1.85.

As shown in FIG. 18, the encapsulation layer group 4 may include a first inorganic layer 41, an organic layer 42, and a second inorganic layer 43 which are stacked in sequence. The first inorganic layer 41 is closer to the display substrate 10 than the second inorganic layer 43. The first inorganic layer 41 may include a base layer 411 and a protruding layer 412, where the base layer 411 is the first film layer 61, and the protruding layer 412 is the second film layer 612; that is, the protruding layer 412 includes a plurality of first protrusions 621 and a plurality of first extensions 622. In this way, the refractive index of the first film layer 61 is the same as that of the second film layer 62, which are both greater than or equal to 1.75 and less than or equal to 1.95. There is no reflection or refraction of light between the first film layer 61 and the second film layer 62. The organic layer 42 is disposed on the side of the first inorganic layer 41 away from the display substrate 10, and the organic layer 42 is the third film layer 63, where the refractive index of the organic layer 42 is greater than or equal to 1.45 and less than or equal to 1.55.

The second inorganic layer 43 is disposed on a side of the organic layer 42 away from the display substrate, and a refractive index of the second inorganic layer 43 is greater than or equal to 1.75 and less than or equal to 1.95.

Moreover, the height of the side wall of the first protrusion 621 in the third direction Z decreases as the distance from the center of the first protrusion 621 on the first plane increases, that is, the side wall of the first protrusion 621 can be provided as an inclined surface. The cross-sectional area of the first protrusion 621 parallel to the first plane decreases as the distance from the display substrate 10 increases. That is, the first protrusion 621 is provided as a right truncated cone or a right prism, and the cross section of the first protrusion 621 perpendicular to the display substrate 10 is a right trapezoid. As shown in FIG. 10, the light emitted from the sub-pixel 35 hits the first protrusion 621. The incident angle of the central light is small without occurring total reflection, and it will pass through the second film layer 62 to the third film layer 63. The incident angle α1 formed between the peripheral light with a larger inclination angle and the first protrusion 621 is much smaller than the original incident angle β1, thereby avoiding total reflection and instead causing refraction, so that the peripheral light with a larger inclination angle can also pass through the first protrusion 621 to the third film layer 63. Moreover, since the light is emitted from the optically dense medium into the optically sparse medium, the refraction angle is larger than the incident angle, so that the emitted light is offset toward the center of the sub-pixel 35, thereby improving the light extraction efficiency of the display panel.

The height of the side wall of the first extension 622 in the third direction Z decreases as the distance from the center of the first extension 622 on the first plane increases. That is, the side wall of the first extension 622 can be provided as an inclined surface. The cross-sectional area of the first extension 622 parallel to the first plane decreases as the distance from the display substrate 10 increases. That is, the first extension 622 is provided as a right prism, and the cross section of the first extension 622 perpendicular to the display substrate 10 is a right trapezoid. Since the orthographic projection of the first extension 622 on the display substrate 10 is located in the area between adjacent sub-pixels 35, the inclination angle of the light emitted from the sub-pixel 35 to the first extension 622 is larger. If the first extension 622 is not provided, these light rays will all be totally reflected and cannot be emitted. After the first extension 622 is provided, the light rays are emitted to the side wall of the first extension 622. Similarly, as shown in FIG. 10, the incident angle a2 formed between these light rays and the first protrusion 621 is much smaller than the original incident angle B2, thereby avoiding total reflection, so that the peripheral light rays with larger inclination angles can also pass through the first extension 622 to the third film layer 63. Moreover, since the light rays are emitted from the optically dense medium to the optically sparse medium, the refraction angle is larger than the incident angle, so that the emitted light rays are offset toward the center position of the sub-pixel 35, thereby further improving the light extraction efficiency of the display panel.

As shown in FIG. 19, the number of the light modulation layer group 6 may be two, and the two groups of light modulation layer groups 6 are the first group 6a and the second group 6b. The display panel may include an encapsulation layer group 4 and a touch layer group 5, the encapsulation layer group 4 is arranged on the light-emitting side of the display substrate 10, and the touch layer group 5 is arranged on the side of the encapsulation layer group 4 away from the display substrate 10. The encapsulation layer group 4 may include a first inorganic layer 41, an organic layer 42 and a second inorganic layer 43. The first inorganic layer 41 is the first film layer 61 of the first group 6a; the organic layer 42 is arranged on the side of the first inorganic layer 41 away from the display substrate 10, the organic layer 42 is the third film layer 63 of the first group 6a, the second film layer 62 of the first group 6a is arranged between the first inorganic layer 41 and the organic layer 42; and the second inorganic layer 43 is arranged on the side of the organic layer 42 away from the first inorganic layer 41. In other words, the first group 6a of the light modulation layer groups 6 has the structure of the light modulation layer group 6 shown in FIG. 17. The first film layer 61 of the second group 6b is the layer farthest from the display substrate 10 in the touch layer group 5, the third film layer 63 of the second group 6b is arranged on the side of the first film layer 61 away from the display substrate 10. A first via is arranged on the third film layer 63, the first recess 631 is the first via arranged on the third film layer 63, the second film layer 62 of the second group 6b is arranged on the side of the third film layer 63 away from the display substrate 10, and a part of the second film layer 62 is located in the first via, thereby forming the first protrusion 621 and the first extension 622. That is, the second group 6b of the light modulation layer groups 6 can be the structure of the light modulation layer group 6 shown in FIG. 12. Alternatively, in some other exemplary embodiments of the present disclosure, the second group 6b of the light modulation layer groups 6 can be the structure of the light modulation layer group 6 shown in FIG. 11, and the specific structure and principle of the light modulation layer group 6 will not be repeated here.

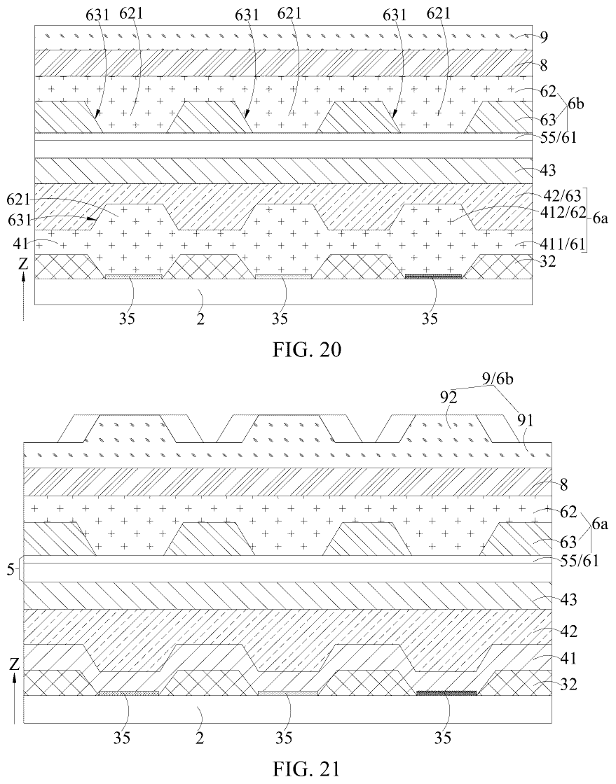

As shown in FIG. 20, the number of the light modulation layer group 6 may be two, and the two groups of light modulation layer groups 6 are the first group 6a and the second group 6b. The display panel may include an encapsulation layer group 4 and a touch layer group 5, where the encapsulation layer group 4 is arranged on the light-emitting side of the display substrate 10, and the touch layer group 5 is arranged on the side of the encapsulation layer group 4 away from the display substrate 10. The encapsulation layer group 4 may include a first inorganic layer 41, an organic layer 42 and a second inorganic layer 43. The first inorganic layer 41 may include a base layer 411 and a protruding layer 412, where the base layer 411 is the first film layer 61 of the first group 6a, and the protruding layer 412 is the second film layer 62 of the first group 6a. The organic layer 42 is arranged on the side of the first inorganic layer 41 away from the display substrate 10, and the organic layer 42 is the third film layer 63 of the first group 6a. The second inorganic layer 43 is arranged on the side of the organic layer 42 away from the display substrate 10; that is, the first group 6a of the light modulation layer groups 6 has the structure of the light modulation layer group 6 shown in FIG. 18. The first film layer 61 of the second group 6b is the layer farthest from the display substrate 10 in the touch layer group 5, and the third film layer 63 of the second group 6b is arranged on the side of the first film layer 61 away from the display substrate 10. A first via is arranged on the third film layer 63, the first recess 631 is the first via arranged on the third film layer 63, the second film layer 62 of the second group 6b is arranged on the side of the third film layer 63 away from the display substrate 10, and a part of the second film layer 62 is located in the first via, thereby forming the first protrusion 621 and the first extension 622. That is, the second group 6b of the light modulation layer groups 6 can be the structure of the light modulation layer group 6 shown in FIG. 12. Alternatively, in some other exemplary embodiments of the present disclosure, the second group 6b of the light modulation layer groups 6 can be the structure of the light modulation layer group 6 shown in FIG. 11, and the specific structure and principle of the light modulation layer group 6 will not be repeated here.

Referring to FIG. 21, the number of the light modulation layer group 6 may be two, and the two groups of light modulation layer groups 6 are the first group 6a and the second group 6b. The first group 6a of the light modulation layer groups 6 may have the structure of the light modulation layer group 6 shown in FIG. 12. The second group 6b of the light modulation layer groups 6 may have the structure of the light modulation layer group 6 shown in FIG. 2.

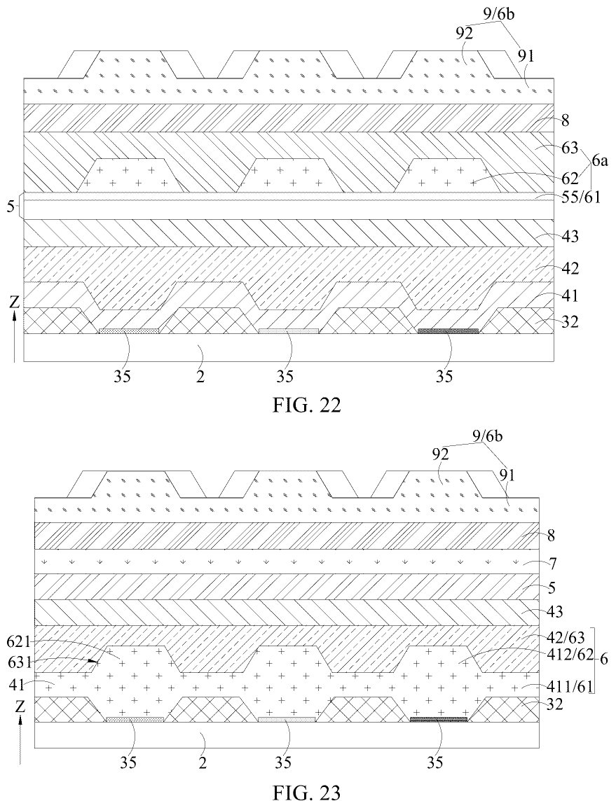

Referring to FIG. 22, the number of the light modulation layer group 6 may be two, and the two groups of light modulation layer groups 6 are the first group 6a and the second group 6b. The first group 6a of the light modulation layer groups 6 may have the structure of the light modulation layer group 6 shown in FIG. 11. The second group 6b of the light modulation layer groups 6 may have the structure of the light modulation layer group 6 shown in FIG. 2.

Referring to FIG. 23, the number of the light modulation layer group 6 may be two, and the two groups of light modulation layer groups 6 are the first group 6a and the second group 6b. The first group 6a of the light modulation layer groups 6 may have the structure of the light modulation layer group 6 shown in FIG. 18. The second group 6b of the light modulation layer groups 6 may have the structure of the light modulation layer group 6 shown in FIG. 2.

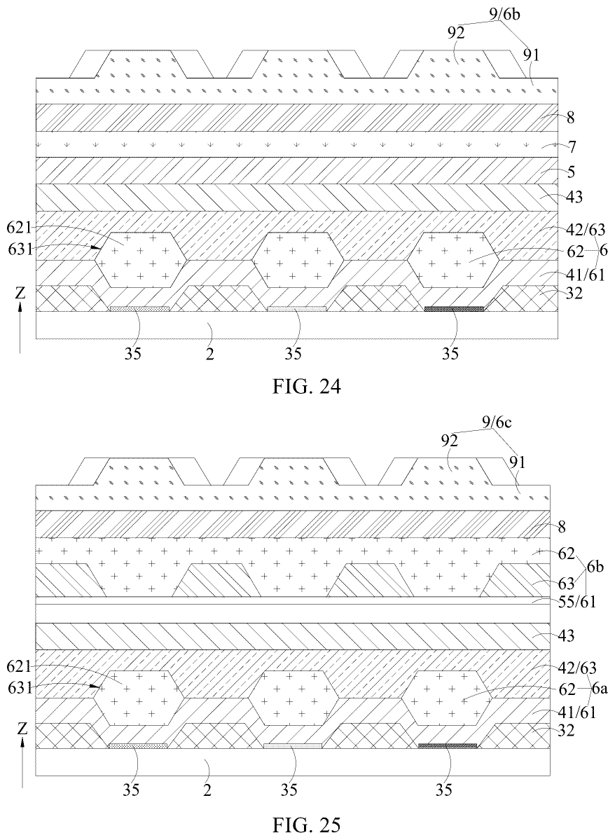

Referring to FIG. 24, the number of the light modulation layer group 6 may be two, and the two groups of light modulation layer groups 6 are the first group 6a and the second group 6b. The first group 6a of the light modulation layer groups 6 may have the structure of the light modulation layer group 6 shown in FIG. 17. The second group 6b of the light modulation layer groups 6 may have the structure of the light modulation layer group 6 shown in FIG. 2. In the structures shown in FIG. 21 to FIG. 24, the second group 6b does not include the third film layer 63.

The two groups of light modulation layer groups 6 are used to converge the light emitted from the sub-pixels 35 at different heights, thereby further improving the light extraction efficiency at the front side of the display panel.

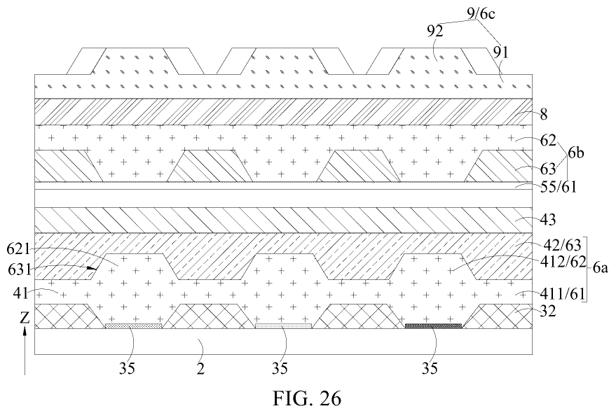

Referring to FIG. 25 and FIG. 26, the number of the light modulation layer groups 6 may be three, and the three groups of light modulation layer groups 6 are the first group 6a, the second group 6b, and the third group 6c.

As shown in FIG. 25, the first group 6a of the light modulation layer groups 6 may have the structure of the light modulation layer group 6 shown in FIG. 17. The first film layer 61 of the second group 6b is the layer farthest from the display substrate 10 in the touch layer group 5. The second group 6b of the light modulation layer groups 6 may have the structure of the light modulation layer group 6 shown in FIG. 12. The third group 6c of the light modulation layer groups 6 may have the structure of the light modulation layer group 6 shown in FIG. 2, that is, the cover plate 9 may include the flat layer 91 and the protruding structure layer 92, where the flat layer 91 is the first film layer 61 of the third group 6c, and the protruding structure layer 92 is the second film layer 62 of the third group 6c. In this case, the third group 6c does not include the third film layer 63.

As shown in FIG. 26, the first group 6a of the light modulation layer groups 6 may have the structure of the light modulation layer group 6 shown in FIG. 18. The first film layer 61 of the second group 6b is the layer farthest from the display substrate 10 in the touch layer group 5. The second group 6b of the light modulation layer groups 6 may have the structure of the light modulation layer group 6 shown in FIG. 12. The third group 6c of the light modulation layer groups 6 may have the structure of the light modulation layer group 6 shown in FIG. 2, that is, the cover plate 9 may include the flat layer 91 and the protruding structure layer 92, where the flat layer 91 is the first film layer 61 of the third group 6c, and the protruding structure layer 92 is the second film layer 62 of the third group 6c. In this case, the third group 6c does not include the third film layer 63.

Alternatively, the light modulation layer group 6 of the second group 6 b may have the structure of the light modulation layer group 6 shown in FIG. 11.

The three groups of light modulation layer groups 6 are used to converge the light emitted from the sub-pixels 35 at different heights, thereby further improving the light extraction efficiency at the front side of the display panel.

It should be noted that all the above-mentioned light modulation layer groups 6 can be applied to any form of pixel arrangement structure.

Based on the same inventive concept, some exemplary embodiments of the present disclosure further provide a display device, which may include any one of the display panels described above. The specific structure of the display panel has been described in detail above, so it will not be repeated here.

The specific type of the display device is not particularly limited, and any type of display device commonly used in the art can be used, for example, mobile devices such as mobile phones, wearable devices such as watches, VR devices, and the like. Those skilled in the art can make corresponding choices based on the specific purpose of the display device, which will not be elaborated here.

It should be noted that, in addition to the display panel, the display device also includes other necessary parts and components, while taking the display as an example, such as a housing, a circuit board, a power cord, and the like. Those skilled in the art can make corresponding supplements based on the specific usage requirements of the display device, which will not be elaborated here.

Compared with the prior art, the beneficial effects of the display device according to some exemplary embodiments of the present invention are the same as the beneficial effects of the display panel according to the above exemplary embodiments, which will not be described in detail herein.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising:
a display substrate and a light modulation layer group, wherein the light modulation layer group is provided on a light-emitting side of the display substrate, the display substrate comprises a plurality of sub-pixels, and the light modulation layer group comprises:
a second film layer, provided on the light-emitting side of the display substrate, wherein the second film layer comprises a plurality of first protrusions and a plurality of first extensions, orthographic projections of the first protrusions on the display substrate overlap with the sub-pixels, and orthographic projections of the first extensions on the display substrate do not overlap with the sub-pixels.

2. The display panel according to claim 1, further comprising:
a first film layer, provided between the display substrate and the second film layer, wherein a difference between a refractive index of the second film layer and a refractive index of the first film layer is less than or equal to 15% of the refractive index of the first film layer.

3. The display panel according to claim 1, wherein a width of the first extension in a first direction is less than or equal to a length of a shortest side, close to the first extension, of an adjacent one of the sub-pixels, and the first direction is parallel to the shortest side.

4. The display panel according to claim 3, wherein the width of the first extension in the first direction is greater than or equal to 0.5 microns and less than or equal to 30 microns.

5. The display panel according to claim 1, wherein an extending direction of the first extension intersects with a first edge of an adjacent one of the sub-pixels with an intersection angle being greater than or equal to 45 degrees, the first edge is a side edge of the sub-pixel close to the first extension, and the extending direction is a direction in which the first protrusion points to the first extension.

6. The display panel according to claim 5, wherein the first extension is connected to the first protrusion.

7. The display panel according to claim 6, wherein a first side line of the first protrusion is connected to one of the first extensions, a width of the first extension in a second direction is less than or equal to a length of the first side line, and the second direction is parallel to the first side line.

8. The display panel according to claim 6, wherein a first side line of the first protrusion is connected to at least two of the first extensions, sum of widths of the at least two of the first extensions in a second direction is less than or equal to a length of the first side line, and the second direction is parallel to the first side line.

9. The display panel according to claim 6, wherein the first extension is connected to a first side line of the first protrusion, and the extending direction of the first extension intersects with the first side line with an intersection angle being greater than or equal to 45 degrees.

10. The display panel according to claim 6, wherein the first extension is connected between adjacent two of the first protrusions.

11. The display panel according to claim 6, wherein the sub-pixels comprise a first sub-pixel and a second sub-pixel adjacent to each other, and the first extension comprises:
a first sub-extension, connected to one of the first protrusions opposite to the first sub-pixel; and
a second sub-extension, connected to one of the first protrusion opposite to the second sub-pixel, wherein a gap is present between the first sub-extension and the second sub-extension;
wherein the first sub-extension is parallel to the second sub-extension, and a width direction of the gap is perpendicular to an extending direction of the first sub-extension; or the first sub-extension is opposite to the second sub-extension, and a width direction of the gap is consistent with an extending direction of the first sub-extension.

12. The display panel according to claim 11, wherein a width of the gap is greater than or equal to 0.5 microns and less than or equal to 15 microns.

13. The display panel according to claim 2, further comprising:
a third film layer, provided on a side of the first film layer away from the display substrate, wherein the third film layer is provided with a first recess, the first recess has at least an opening facing the first film layer, the refractive index of the first film layer is greater than a refractive index of the third film layer, the refractive index of the second film layer is greater than the refractive index of the third film layer, the first extension is located within the first recess, and the first protrusion is located within the first recess.

14. The display panel according to claim 13, wherein the display panel comprises:
a touch layer group provided on the light-emitting side of the display substrate, wherein the first film layer is a layer of the touch layer group farthest from the display substrate.

15. The display panel according to claim 14, wherein the touch layer group comprises touch grid lines, and orthographic projections of the touch grid lines on the display substrate do not overlap with the sub-pixels; and
wherein the first film layer covers the display substrate; or wherein the first film layer comprises a first part and a second part spaced apart from each other, an orthographic projection of the first part on the display substrate covers the sub-pixels, and the orthographic projections of the touch grid lines on the display substrate are located within an orthographic projection of the second part on the display substrate.

16. The display panel according to claim 13, wherein the display panel comprises an encapsulation layer group provided on the light-emitting side of the display substrate, and the encapsulation layer group comprises:
a first inorganic layer, being the first film layer;
an organic layer, provided on a side of the first inorganic layer away from the display substrate, wherein the organic layer is the third film layer, and the second film layer is provided between the first inorganic layer and the organic layer; and
a second inorganic layer, provided on a side of the organic layer away from the display substrate.

17. The display panel according to claim 13, wherein the display panel comprises an encapsulation layer group provided on the light-emitting side of the display substrate, and the encapsulation layer group comprises:
a first inorganic layer, comprising a base layer and a protruding layer, wherein the base layer is the first film layer, and the protruding layer is the second film layer;
an organic layer, provided on a side of the first inorganic layer away from the display substrate, wherein the organic layer is the third film layer; and
a second inorganic layer, provided on a side of the organic layer away from the display substrate.

18. The display panel according to claim 14, wherein the second film layer is provided on a side of the first film layer away from the display substrate, the third film layer is provided on a side of the second film layer away from the display substrate, and at least part of the third film layer is located between adjacent ones of the first protrusions, between the first protrusion and the first extension, and between adjacent ones of the first extensions, thereby forming the first recess on the third film layer.

19. The display panel according to claim 18, wherein a height of a side wall of the first protrusion in a third direction decreases as a distance from a center of the first protrusion on a first plane increases, a height of a side wall of the first extension in the third direction decreases as a distance from a center of the first extension on the first plane increases, the first plane is parallel to a surface of the display substrate close to the first film layer, and the third direction is perpendicular to the first plane.

20-34. (canceled)

35. A display device, comprising: a display panel, wherein the display panel comprises:
a display substrate and a light modulation layer group, wherein the light modulation layer group is provided on a light-emitting side of the display substrate, the display substrate comprises a plurality of sub-pixels, and the light modulation layer group comprises:
a second film layer, provided on the light-emitting side of the display substrate, wherein the second film layer comprises a plurality of first protrusions and a plurality of first extensions, orthographic projections of the first protrusions on the display substrate overlap with the sub-pixels, and orthographic projections of the first extensions on the display substrate do not overlap with the sub-pixels.
